(19) United States
(12) Patent Application Publication
(10) Pub. No.: US 2020/0317948 A1
(43) Pub. Date: Oct. 8, 2020

(54) DISPERSION, AND METHODS FOR PRODUCING METAL LAMINATE AND PRINTED BOARD

(71) Applicant: AGC Inc., Chiyoda-ku (JP)

(72) Inventors: Tatsuya Terada, Chiyoda-ku (JP); Tomoya Hosoda, Chiyoda-ku (JP); Atsumi Yamabe, Chiyoda-ku (JP)

(73) Assignee: AGC Inc., Chiyoda-ku (JP)

(21) Appl. No.: 16/904,645

(22) Filed: Jun. 18, 2020

Related U.S. Application Data
(63) Continuation of application No. PCT/JP2018/047952, filed on Dec. 26, 2018.

(30) Foreign Application Priority Data
Dec. 27, 2017 (JP) 2017-252475
May 16, 2018 (JP) 2018-094781
Aug. 29, 2018 (JP) 2018-160700

(51) Int. Cl. C09D 127/18; B05D 7/14; C08J 3/11; C09D 7/65; H05K 3/06; H05K 1/03

(52) U.S. Cl. CPC C09D 127/18; B05D 7/14; C08J 3/11; C08J 2327/18; H05K 3/06; H05K 1/0353; C09D 7/65

(57) ABSTRACT

To provide a dispersion excellent in miscibility with varnish, coating properties, dispersibility and dispersion stability; and methods for producing a metal laminate and a printed board. A dispersion comprises an organic solvent and a powder so that the powder is dispersed in the organic solvent, wherein the powder is a powder containing a tetrafluoroethylene type polymer having a melt viscosity at 380° C. of from 1×10² to 1×10⁶ Pa·s; the viscosity is from 50 to 10,000 mPa·s; and the thixotropy ratio calculated by dividing the viscosity measured under the condition of rotational speed of 30 rpm by the viscosity measured under the condition of rotational speed of 60 rpm, is from 1.0 to 2.2.

### TECHNICAL FIELD

The present invention relates to a dispersion, and methods for producing a metal laminate and a printed board.

### BACKGROUND ART

A fluoropolymer such as polytetrafluoroethylene (PTFE) is excellent in physical properties such as chemical resistance, water and oil repellency, heat resistance, electrical properties, etc., and various applications utilizing its properties, and various modes of use such as powders, films, etc., have been proposed (see Patent Documents 1 to 3).

In recent years, the fluoropolymer has been attracting attention as a material for printed boards of electronic products, in particular, as an insulating material for printed boards corresponding to the frequency of a high frequency band, or as an insulating material having electric properties such as a low permittivity, low dielectric dissipation factor, etc. and heat resistance to withstand solder reflow.

As such an insulating material, Patent Document 4 discloses a method for producing a printed board, which comprises coating and drying, on the surface of a metal foil, a mixture of PTFE and a varnish containing another insulating resin such as polyimide, to produce a metal laminate having an insulating resin layer formed, and further subjecting the metal foil of the metal laminate to etching treatment to form a transmission line. Further, Patent Document 5 discloses, as the PTFE dispersion for forming such a varnish, a dispersion containing a PTFE powder.

### PRIOR ART DOCUMENTS

### Patent Documents

Patent Document 1: JP-A-2012-162708

Patent Document 2: JP-A-2005-142572

Patent Document 3: WO2016/017801

Patent Document 4: JP-A-2015-509113

Patent Document 5: WO2016/159102

### DISCLOSURE OF INVENTION

### Technical Problem

In the embodiment described in Patent Document 4, from the viewpoint of the electrical characteristics of an obtainable printed board, it is required that another insulating resin and a fluoropolymer are mixed in a good condition, but the control for such requirement is not easy. For example, at the time of mixing and adjusting a varnish containing another resin and a powder of a fluoropolymer, due to the thickening, not only mixing itself becomes to be difficult, but also dispersibility of the fluoropolymer after preparation becomes to be significantly reduced.

Also in the embodiment described in Patent Document 5, dispersibility and dispersion stability of the fluoropolymer in the dispersion are not still sufficient, and the coating property is low. In particular, if the amount of the powder of the fluoropolymer is reduced to improve the dispersibility of the dispersion, not only the coating property will be lowered, but also the physical properties of the formed insulating layer will decrease.

It is an object of the present invention to provide a dispersion containing a powder of tetrafluoroethylene type polymer, which is excellent in a mixing property with a different type of resin material or its varnish and which is excellent in the coating property, dispersibility and dispersion stability.

### Solution to Problem

The present invention has the following embodiments.

[1] A dispersion comprising an organic solvent and a powder so that the powder is dispersed in the organic solvent, wherein the powder is a powder containing a tetrafluoroethylene type polymer with a melt viscosity at 380° C. of from 1×10² to 1×10⁶ Pa·s; the viscosity is from 50 to 10,000 mPa·s; and the thixotropy ratio calculated by dividing the viscosity measured under the condition of rotational speed of 30 rpm by the viscosity measured under the condition of rotational speed of 60 rpm is from 1.0 to 2.2.
[2] The dispersion according to [1], wherein the viscosity is from 100 to 10,000 mPa·s, and the thixotropy ratio is from 1.4 to 2.2.
[3] The dispersion according to [1], wherein the viscosity is from 50 to 3,000 mPa·s, and the thixotropy ratio is from 1.0 to 1.5.
[4] The dispersion according to any one of [1] to [3], wherein the powder is a powder having a volume-reduced cumulative 50% diameter of from 0.05 to 4 μm and a volume-reduced cumulative 90% diameter of at most 8 μm.
[5] The dispersion according to any one of [1] to [4], wherein the tetrafluoroethylene type polymer contains units derived from a comonomer other than tetrafluoroethylene in an amount exceeding 0.5 mol % to all units of the polymer.
[6] The dispersion according to any one of [1] to [5], wherein the tetrafluoroethylene type polymer is a copolymer of tetrafluoroethylene and ethylene, a copolymer of tetrafluoroethylene and a perfluoro(alkyl vinyl ether), a copolymer of tetrafluoroethylene and hexafluoropropylene, or a tetrafluoroethylene type polymer having at least one type of functional group selected from the group consisting of a carbonyl group-containing group, a hydroxy group, an epoxy group, an amide group, an amino group and an isocyanate group.
[7] The dispersion according to any one of [1] to [4], wherein the tetrafluoroethylene type polymer is a polytetrafluoroethylene containing units derived from tetrafluoroethylene in an amount of at least 99.5 mol %, to all units of the polymer.
[8] The dispersion according to any one of [1] to [7], wherein the organic solvent is methyl ethyl ketone, toluene, xylene, cyclohexane, methylcyclohexane, cyclohexanone, cyclopentanone, N,N-dimethylacetamide or N-methyl-2-pyrrolidone.
[9] The dispersion according to any one of [1] to [8], wherein the content of the powder is from 5 to 50 mass %, to the total of the organic solvent and the powder.
[10] The dispersion according to any one of [1] to [9], which further contains a surfactant.
[11] The dispersion according to [10], wherein the surfactant is a surfactant having a fluorinated group and a hydrophilic group.
[12] The dispersion according to [11], wherein the hydrophilic group which the surfactant has, is a polyoxyethylene group, a polyoxypropylene group, an oxybutylene group, an amino group, a ketone group, a carboxy group or a sulfonic group.
[13] The dispersion according to [11] or [12], wherein the fluorinated group which the surfactant has, is a perfluoroalkyl group or a perfluoroalkenyl group.
[14] The dispersion according to any one of [10] to [13], wherein the surfactant is a polymeric compound having a fluorinated hydrocarbon group and a hydrophilic group in a side chain, wherein the main chain is made of a carbon chain derived from an ethylenically unsaturated monomer, and said fluorinated hydrocarbon group is a group having a tertiary carbon atom to which a plurality of monovalent fluorinated hydrocarbon groups are bonded.
[15] The dispersion according to any one of [1] to [14], wherein the content of the powder is from 35 to 70 mass % to the total of the organic solvent, the powder and the surfactant.
[16] A method for producing a metal laminate, which comprises forming a dispersion as defined in any one of [1] to [15] into a resin layer on the surface of a metal film to obtain a metal film having a resin layer on the surface.
[17] The method for producing a metal laminate according to [16], wherein the thickness of the resin layer is from 1 to 20 μm.
[18] A method for producing a printed board, which comprises producing a metal laminate by the production method as defined in [16] or [17] and etching the metal film to form a patterned circuit.

### Advantageous Effects of Invention

According to the present invention, it is possible to obtain a dispersion which is excellent in a mixing property with a different type of resin material or its varnish and which is excellent in the coating property, dispersibility and dispersion stability, and to provide a material for a metal laminate for producing a printed board corresponding to the frequency of high frequency band, excellent in physical properties such as electrical properties and heat resistance.

### DESCRIPTION OF EMBODIMENTS

In this specification, meanings of the following terms are as follows.

The “volume-reduced cumulative 50% diameter of the powder” is obtainable by a laser diffraction scattering method. That is, the particle size distribution is measured by a laser diffraction scattering method, and the cumulative curve is obtained based on the total volume of the population of particles as 100%, whereby it is the particle diameter at a point where the cumulative volume becomes 50% on the cumulative curve. In this specification, the volume-reduced cumulative 50% diameter of the powder is referred to also as “D50”.

The “volume-reduced cumulative 90% diameter of the powder” is obtainable by a laser diffraction scattering method. That is, the particle size distribution is measured by a laser diffraction scattering method, and the cumulative curve is obtained based on the total volume of the population of particles as 100%, whereby it is a particle diameter at a point where the cumulative volume becomes 90% on the cumulative curve. In this specification, the volume-reduced cumulative 90% diameter of the powder is referred to also as “D90”.

The “melt viscosity” means a melt viscosity measured in accordance with ASTM D1238 by using a flow tester and a 2ϕ-8L die, by maintaining a polymer sample (2 g) preliminarily heated at the measuring temperature for 5 minutes, at the measuring temperature under a load of 0.7 MPa.

The “melting point” is a temperature corresponding to the maximum value of the melting peak of a polymer as measured by a differential scanning calorimetry (DSC) method.

The “viscosity of a dispersion” is a value measured by using a B-type viscometer at room temperature (25° C.) under a condition of rotational speed of 30 rpm. The measurement is repeated three times, and an average value of the measured values of three times is adopted.

The “thixotropy ratio of a dispersion” is a value (η₁/η₂) calculated by dividing the viscosity η₁ measured under a condition of rotational speed of 30 rpm by the viscosity η₂ measured under a condition of rotational speed of 60 rpm. The measurement of each viscosity is repeated three times, and an average value of the measured values of three times is adopted.

The “relative permittivity” is a value obtained at 1 MHz by a dielectric breakdown test device by maintaining the temperature within a range of 23° C.±2° C. and the relative humidity within a range of 50%±5% RH by a transformer bridge method in accordance with ASTM D150.

The “surface tension of an organic solvent” is a value measured at 25° C. by using a surface tension meter.

The dispersion of the present invention is a dispersion which comprises an organic solvent and a powder containing a tetrafluoroethylene type polymer with a specific viscosity (hereinafter referred to also as a “TFE type polymer”), wherein the viscosity and thixotropy ratio are within the predetermined ranges.

By using the specific TFE type polymer and adjusting the type and proportion of the organic solvent, the viscosity and thixotropy ratio are made to be within the predetermined ranges.

The reason as to why the dispersion of the present invention is excellent in the dispersibility, the mixing property with a different type of resin material and its varnish and the coating property, is not necessarily clear, but it is considered as follows.

In the present invention, the TFE type polymer is selected from powders of TFE type polymers with a specific viscosity (the melt viscosity at 380° C. being from 1×10² to 1×10⁶ Pa·s), and in other words, it can be said that it is selected from powders of TFE type polymers having a low molecular weight and/or a high polarity. With such a powder, it is considered that not only from the physical viewpoint such that the specific surface area is large, but also from the chemical viewpoint such as a distribution state of polymer chains at the surface, aggregation or precipitation in an properly selected organic solvent will be suppressed, whereby a stabilized dispersed state will be formed. As a result, with the dispersion of the present invention, the viscosity and thixotropy ratio of the dispersion are considered to be within the predetermined ranges, and it is considered to be excellent in the coating property and the mixing property with a different type of resin material or its varnish. Further, the dispersion in the present invention is therefore excellent in re-dispersibility at a low temperature.

Further, when a specific surfactant (having a fluorinated group and a hydrophilic group) is present, these effects tend to be readily exhibited, since the surfactant and the powder will be in such a state that they interact easily.

From the viewpoint of adjusting the viscosity and thixotropy, the dispersion of the present invention may further contain a thixotropic agent or a defoaming agent. Further, from the above viewpoint, the dispersion of the present invention preferably does not contain a resin which will be dissolved in the organic solvent.

The viscosity of the dispersion of the present invention is from 50 to 10,000 mPa·s, more preferably from 70 to 5,000 mPa·s, further preferably from 100 to 3,000 mPa·s, particularly preferably from 150 to 1,000 mPa·s. When the viscosity is at least 50 mPa·s, dispersion stability of the dispersion will be excellent. When the viscosity is at most 10,000 mPa·s, it will be easy to form a film from the dispersion, and dispersibility and coating property of the dispersion will be excellent.

The viscosity of the dispersion of the present invention is preferably from 100 to 10,000 mPa·s, more preferably from 130 to 7,000 mPa·s, further preferably from 150 to 5,000 mPa·s, particularly preferably from 170 to 3,000 mPa·s. In this case, it will be easy to form a uniform film from the dispersion, and dispersion stability and coating property of the dispersion will be more excellent.

The viscosity of the dispersion of the present invention may be said to be preferably from 50 to 3,000 mPa·s, more preferably from 70 to 1,500 mPa·s, further preferably from 80 to 1,000 mPa·s, particularly preferably from 100 to 500 mPa·s. In this case, the coating property will be excellent in the case of forming a varnish with a different type of resin material from the dispersion.

The thixotropy ratio of the dispersion of the present invention is from 1.0 to 2.2. When the thixotropy ratio is at most 2.2, it will be easy to form a film from the dispersion, and the dispersibility and coating property of the dispersion will be excellent.

The thixotropy ratio of the dispersion is preferably from 1.4 to 2.2, more preferably from 1.45 to 2.10, further preferably from 1.5 to 2.0. In this case, it will be easy to form a uniform film from the dispersion, and the dispersion stability and coating property of the dispersion will be more excellent.

The thixotropy ratio of the dispersion is preferably from 1.0 to 1.5, more preferably from 1.05 to 1.45, further preferably from 1.1 to 1.4, particularly preferably from 1.1 to 1.3. In this case, the mixing property of the dispersion and a varnish of a different type of resin material will be excellent.

The powder in the present invention contains a tetrafluoroethylene type polymer with a melt viscosity at 380° C. of from 1×10² to 1×10⁶ Pa·s (TFE type polymer).

The powder may contain components other than the TFE type polymer, to such an extent not to impair the effects of the present invention, but is preferably one composed mainly of the TFE type polymer. The content of the TFE type polymer in the powder is preferably at least 80 mass %, more preferably at least 90 mass %, particularly preferably 100 mass %.

D50 of the powder is from 0.05 to 4 μm, and D90 is preferably at most 8 μm.

D50 of the powder is preferably from 0.1 to 3 μm, particularly preferably from 0.2 to 3.0 μm. Within this range, the flowability and dispersibility of the powder become excellent, and the coating property and mixing property with a varnish of a different type of resin material, of the dispersion will be excellent. Moreover, in an article (a metal laminate, printed board or the like) obtainable from the dispersion of the present invention, electrical properties (a low permittivity, etc.) and heat resistance of the TFE type polymer tend to be most easily expressed. Further, the thickness of the film obtainable from the dispersion of the present invention can easily be controlled.

D90 of the powder is preferably at most 6 μm, particularly preferably from 1.5 to 5 μm. Within this range, the dispersibility of the powder becomes good; the coating property and mixing property with a varnish of a different type of resin material, of the dispersion, will be excellent; and it will be easy to improve the uniformity of the film obtainable from the dispersion.

The loose packing bulk density of the powder is preferably at least 0.05 g/mL, particularly preferably from 0.08 to 0.5 g/mL.

The densely packing bulk density of the powder is preferably at least 0.05 g/mL, particularly preferably from 0.1 to 0.8 g/mL.

Of the TFE type polymer in the present invention, the melt viscosity at 340° C. is preferably from 1×10² to 1×10⁶ Pa·s, and the melt viscosity at 300° C. is particularly preferably from 1×10² to 1×10⁶ Pa·s.

The relative permittivity of the TFE type polymer (measurement frequency: 1 MHz) is preferably at most 2.5, particularly preferably at most 2.4. As the relative permittivity of the TFE type polymer is low, the transmission characteristics of the printed board will be further excellent. The lower limit value for the relative permittivity is normally 2.0. The relative permittivity of the TFE type polymer can be adjusted by the proportion of units (hereinafter referred to also as “TFE units”) derived from tetrafluoroethylene (hereinafter referred to also as “TFE”) (the same applies to other units).

The TFE type polymer may be a homopolymer of TFE or a copolymer of TFE and another monomer (monomer copolymerizable with TFE; hereinafter referred to also as a comonomer). Further, the TFE type polymer preferably contains TFE units in an amount of at least 90 mol % to all units contained in the polymer.

Preferred specific examples of the TFE type polymer may be the later-described polytetrafluoroethylene (hereinafter referred to also as PTFE) with a low molecular weight and the later-described polymer A.

PTFE with a low molecular weight may be not only PTFE wherein the melt viscosity at 380° C. is from 1×10² to 1×10⁶ Pa·s as the entire polymer, but also PTFE wherein in a core-shell structure composed of a core portion and a shell portion, only the shell portion satisfies the above melt viscosity.

PTFE with a low molecular weight may be PTFE obtainable by irradiating PTFE having a high molecular weight (PTFE having a melt viscosity of from 1×10⁹ to 1×10¹⁰ Pa·s) with radiation (WO2018/026012, WO2018/026017, etc.), or PTFE obtainable by using a chain transfer agent at the time of producing PTFE by polymerizing TFE (JP-A-2009-1745, WO2010/114033, etc.).

Further, PTFE may be a polymer obtained by polymerizing TFE alone, or may be a copolymer obtained by copolymerizing TFE and a comonomer (WO2009/20187, etc.). In this case, TFE units are preferably at least 99.5 mol %, more preferably at least 99.8 mol %, further preferably at least 99.9 mol %, to all units contained in the polymer. As the comonomer, a fluoromonomer to be described later may be mentioned, and hexafluoropropylene (hereinafter referred to also as HFP), a perfluoro (alkyl vinyl ether) (hereinafter referred to also as PAVE) or a fluoroalkyl ethylene (hereinafter referred to also as FAE) is preferred.

PTFE having a core-shell structure may be PTFE as described in e.g. JP-A-2005-527652, WO2016/170918, etc. In order to bring the melt viscosity of the shell portion to be within the above range, it is possible to employ a method of making the shell portion to be a low molecular weight by using a chain transfer agent (JP-A-2015-232082, etc.) or a method of copolymerizing TFE and the above-mentioned comonomer at the time of producing the shell portion (JP-A-H09-087334).

In the latter method, the amount of the comonomer to be used is preferably from 0.001 to 0.05 mol % to TFE. Further, not only the shell portion, but also the core portion may be prepared by copolymerization.

The standard specific gravity to be measured in accordance with ASTM D4895-04, of PTFE with a low molecular weight, is preferably from 2.14 to 2.22, more preferably from 2.16 to 2.20.

Polymer A is a copolymer of TFE and a comonomer, and contains units derived from a comonomer in an amount exceeding 0.5 mol % to all units contained in the polymer. The melting point of the polymer A is preferably from 260 to 320° C., particularly preferably from 295 to 310° C. When the melting point of the polymer A is at least the lower limit value in the above range, it will be excellent in heat resistance. When the melting point of the polymer A is at most the upper limit value in the above range, it will be excellent in melt moldability.

The polymer A may be a copolymer of ethylene and TFE (ETFE), a copolymer of TFE and HFP (FEP), or a copolymer of TFE and PAVE (PFA). As the polymer A, from the viewpoint of the electrical properties (permittivity, dissipation factor) and heat resistance, PFA or FEP is more preferred, and PFA is further preferred.

The TFE type polymer may have at least one type of functional group selected from the group consisting of a carbonyl group-containing group, a hydroxy group, an epoxy group, an amide group, an amino group and an isocyanate group, from such a viewpoint that adhesion between the resin layer and the substrate will be further excellent.

The TFE type polymer may have a functional group in a terminal group of the polymer main chain, or may have a functional group in the polymer side chain.

The former TFE type polymer may be a polymer which is produced by using a polymerization initiator or a chain transfer agent having the above functional group, or a polymer which is produced by modifying the terminal group in the main chain of the TFE type polymer. As such a functional group, an alkoxycarbonyl group, a carbonate group, a carboxy group, a fluoroformyl group, an acid anhydride residue and a hydroxy group are preferred.

The latter TFE type polymer is preferably a polymer A having units having the above functional group (hereinafter referred to as “functional units”).

Further, a TFE type polymer having a functional group may be adjusted by a method of treating a powder of the TFE type polymer with a surface treating agent (a solution containing a complex of metal sodium and naphthalene, etc.), or a method of treating the TFE type polymer with plasma irradiation, corona irradiation, electron beam irradiation or radiation irradiation.

Hereinafter, the present invention will be described with reference to a case, as an example, wherein the TFE type polymer is a polymer A having TFE units, HFP units, PFA units or FAE units, and functional units. Here, units derived from TFE, contained in the polymer are referred to as TFE units. The same applies to other units.

Functional units are preferably units derived from a monomer having a carbonyl group-containing group, from such a viewpoint that the polymer A will be excellent in mechanical grindability and fusibility with a metal.

The carbonyl group-containing group is preferably a carbonate group, a carboxy group, a haloformyl group, an alkoxycarbonyl group or an acid anhydride residue, and a carboxy group or an acid anhydride residue is more preferred.

The monomer having a carbonyl group-containing group may be an unsaturated dicarboxylic acid such as itaconic acid, citraconic acid, 5-norbornene-2,3-dicarboxylic acid or maleic acid, or an unsaturated monocarboxylic acid such as acrylic acid or methacrylic acid.

The monomer having an acid anhydride residue may be an unsaturated dicarboxylic acid anhydride, and itaconic anhydride, citraconic anhydride, 5-norbornene-2,3-dicarboxylic anhydride (another name: Nadic anhydride, hereinafter referred to also as “NAH”) and maleic anhydride are preferred.

PAVE may be CF₂═CFOCF₃, CF₂═CFOCF₂CF₃, CF₂═CFOCF₂CF₂CF₃ (hereinafter referred to also as “PPVE”), CF₂═CFOCF₂CF₂CF₂CF₃, CF₂═CFO(CF₂)₈F, etc., and PPVE is preferred.

FAE may be CH₂═CH(CF₂)₂F, CH₂═CH(CF₂)₃F, CH₂═CH(CF₂)₄F, CH₂═CF(CF₂)₃H, CH₂CF═(CF₂)₄H, etc., and CH₂═CH(CF₂)₄F and CH₂═CH(CF₂)₂F are preferred.

Such polymers A may be polymers described in WO2018/16644, and preferred is a polymer wherein among all units constituting the polymer A, the proportion of TFE units is from 90 to 99 mol %, the proportion of PAVE units is from 0.5 to 9.97 mol % and the proportion of functional units is from 0.01 to 3 mol %.

The organic solvent in the present invention is a compound that does not react with the powder, is a compound which has a lower boiling point than the respective components contained in the dispersion of the present invention, and is preferably a compound which tends to readily volatilize by e.g. heating, and is thus easily removable. The boiling point of the organic solvent is preferably at most 270° C., more preferably from 70 to 260° C. As the organic solvent, an organic solvent having no fluorine atom is preferred.

As specific examples of the organic solvent, the following compounds may be mentioned.

γ-Butyrolactone, acetone, methyl ethyl ketone, hexane, heptane, octane, 2-heptanone, cycloheptanone, cyclohexanone, cyclohexane, methylcyclohexane, ethylcyclohexane, methyl-n-pentyl ketone, methyl isobutyl ketone, methyl isopentyl ketone.

Ethylene glycol, diethylene glycol, propylene glycol, dipropylene glycol, ethylene glycol monoacetate, ethylene glycol monomethyl ether acetate, ethylene glycol monoethyl ether acetate, diethylene glycol acetate, diethylene glycol diethyl ether, propylene glycol monoacetate, dipropylene glycol monoacetate, propylene glycol diacetate, propylene glycol monomethyl ether, propylene glycol monomethyl ether acetate, propylene glycol monoethyl ether acetate, cyclohexyl acetate, ethyl 3-ethoxypropionate, dioxane, methyl lactate, ethyl lactate, methyl acetate, ethyl acetate, butyl acetate, methyl pyruvate, ethyl pyruvate, methyl methoxypropionate, ethyl ethoxypropionate.

Anisole, ethylbenzyl ether, cresyl methyl ether, diphenyl ether, dibenzyl ether, phenetole, butyl phenyl ether, benzene, ethylbenzene, diethylbenzene, pentylbenzene, isopropylbenzene, toluene, xylene, cymene, mesitylene.

Methanol, ethanol, isopropanol, butanol, methyl monoglycidyl ether, ethyl monoglycidyl ether, dimethylformamide, mineral spirits, N,N-dimethylformamide, N,N-dimethylacetamide, N-methyl-2-pyrrolidone, various silicone oils.

The organic solvent is preferably a compound having a boiling point of from 70 to 260° C. selected from the group consisting of ketones, esters, amides and aromatic hydrocarbons, more preferably a compound having a boiling point of from 100 to 240° C. selected from the group consisting of aromatic hydrocarbons, chain ketones, cyclic ketones, lactones and lactams, particularly preferably a cyclic ketone or lactam having a boiling point of from 100 to 240° C.

Specific examples of the ketone may be methyl ethyl ketone, methyl isobutyl ketone, 2-heptanone, cycloheptanone and cyclohexanone.

Specific examples of the ester may be ethyl acetate, butyl acetate and γ-butyrolactone.

Specific examples of the amide may be N-dimethylformamide and N-methyl-2-pyrrolidone.

Specific examples of the aromatic hydrocarbon may be toluene and xylene.

In a case where the viscosity of the dispersion of the present invention is from 100 to 10,000 mPa·s, and the thixotropy ratio is from 1.4 to 2.2, the surface tension of the organic solvent is preferably at most 30 dyn/cm, more preferably at most 29 dyn/cm, further preferably at most 28.5 dyn/cm. In this case, the wettability of the organic solvent to the surface of the powder will be improved, whereby the powder tends to be easily dispersed in the organic solvent, and the thixotropy ratio of the dispersion tends to easily converge within the predetermined range.

Specific examples of the organic solvent, of which the surface tension is at most 30 dyn/cm, may be methyl ethyl ketone, toluene, xylene, cyclohexane, methylcyclohexane, etc.

In a case where the viscosity of the dispersion of the present invention is from 50 to 3,000 mPa·s and the thixotropy ratio is from 1.0 to 1.5, the surface tension of the organic solvent is preferably more than 30 dyn/cm, more preferably more than 31 dyn/cm, further preferably more than 32 dyn/cm. In this case, the polarity of the organic solvent becomes high; a surfactant tends to be readily adsorbed on the surface of the powder particles; the powder tends to be more readily dispersed in single particles in the organic solvent; the thixotropy ratio of the dispersion tends to readily converge within the predetermined range; and the mixing property of the dispersion and a varnish of a different type of resin material will further be excellent.

Specific examples of the organic solvent, of which the surface tension is more than 30 dyn/cm, may be cyclohexanone, cyclopentanone, N,N-dimethylacetamide, N-methyl-2-pyrrolidone, etc.

In the present invention, a surfactant may be used.

The surfactant in the present invention has such a nature that under a condition where an external force such as a shear force is weak, it tends to bind between the powder and the organic solvent, and under a condition where an external force such as a shear force is strong, it tends to be dissociated from between the powder and the organic solvent. Therefore, the dispersion of the present invention containing the surfactant tends to be such that the thixotropy ratio tends to readily converge within the predetermined range, and even when left to stand still like during storage or the like, agglomeration of the powder is less likely to occur, and its dispersion stability will be excellent.

For example, if the powder is dispersed as it is in a polar organic solvent such as methyl ethyl ketone, interaction between the powder particles is strong, and the powder particles tend to repel with the polar organic solvent, whereby powder particles tend to be easily aggregated. In contrast, when the dispersion of the present invention contains such a surfactant, the surfactant tends to bond between the powder particles. Therefore, it is possible to weaken the interaction between the powder particles, whereby agglomeration of the powder tends to be less likely to occur. As a result, the dispersion of the present invention will be excellent in dispersion stability.

When the dispersion of the present invention contains a surfactant, the powder tends to be readily dispersed in single particles. Therefore, it is possible to suppress agglomeration of the powder at the time of wetting the powder in the organic solvent, and even after the dispersion, it is possible to suppress agglomeration of the powder, and the dispersion shows good dispersibility. As a result, the dispersion of the present invention is excellent in the mixing property with the varnish.

In a case where the TFE type polymer has functional groups, if the powder is dispersed as it is, for example, in a polar organic solvent, the interaction of the functional groups and the organic solvent tends to be strong. Therefore, the viscosity of the obtainable dispersion becomes high, and it tends to be mousse. In contrast, since the dispersion of the present invention contains a surfactant, it is possible to weaken the interaction between the functional groups and the organic solvent, and even when the TFE type polymer has functional groups, it is possible to suppress the viscosity of the dispersion. Accordingly, it is possible to easily form a film, and the dispersion is excellent in coating property and excellent in dispersibility.

In a case where the surfactant in the present invention has a fluorinated group and a hydrophilic group, the surface tension of the organic solvent as a dispersion medium decreases, whereby the wettability to the powder surface of the organic solvent will be improved. Therefore, the powder tends to be easily dispersed in the organic solvent, and the dispersion will be excellent in dispersibility. Further, the fluorinated group tends to be easily adsorbed on the powder surface having fluorine atoms, and the hydrophilic group tends to be easily extended in the organic solvent, whereby agglomeration of the powder is suppressed by the steric hindrance of the hydrophilic group. As a result, the dispersion will be excellent in dispersion stability. Especially when the TFE type polymer has adhesive groups, this effect becomes remarkable.

The fluorinated group may be a group having a high hydrophobicity such as a perfluoroalkyl group, or a perfluoroalkenyl group (hexafluoropropylene trimer group, etc.). The number of carbon atoms in the fluorinated group is preferably 2 or more, more preferably from 4 to 20. From such a viewpoint that the fluorinated group will be excellent in bulky adsorption capacity, —CF(CF₃)C(═C(CF₃)₂)(CF(CF₃)₂) is preferred.

The hydrophilic group is a relatively hydrophilic group to the fluorinated group, and may be a common hydrophilic group, or may be a relatively hydrophilic group to the fluorinated group even if it is usually deemed to be a hydrophobic group. For example, a polyoxypropylene group is relatively hydrophobic to a polyoxyethylene group being a hydrophilic group, and it is usually deemed to be a hydrophobic group, but its hydrophobicity is relatively low to a fluorinated group, and thus, it is a hydrophilic group in the present invention.

The hydrophilic group may be ethylene oxide (a polyoxyethylene group), propylene oxide (a polyoxypropylene group), butylene oxide (a polyoxybutylene group), a polyoxytetramethylene group, an amino group, a ketone group, a carboxy group or a sulfonic group. As the hydrophilic group, a polyoxyalkylene group made of a C2-4 oxyalkylene group is preferred, and a polyoxyethylene group is particularly preferred.

The surfactant may also be a copolymer of a monomer having a fluorinated group and a monomer having a hydrophilic group. As such a surfactant, particularly preferred is a copolymer of a monomer having a fluorinated group and a monomer having a polyoxyalkylene group.

The mass average molecular weight of the surfactant is preferably from 1,000 to 150,000, more preferably from 5,000 to 100,000, further preferably from 10,000 to 50,000. When the molecular weight of the surfactant is at least the lower limit value in the above range, the surfactant tends to have stronger adsorbability to the surface of the powder than the organic solvent, whereby the dispersion will be further excellent in dispersibility and dispersion stability.

When the mass average molecular weight of the surfactant is at most the upper limit value in the above range, the dispersion will be further excellent in coating property. The mass average molecular weight of the surfactant is a value measured by gel permeation chromatography (GPC).

As the surfactant in the present invention, a nonionic surfactant is preferred.

As the surfactant, the most suitable compound is selected depending on the types of the fluororesin and the organic solvent. In a case where two or more types of surfactant are used in combination, at least one type is preferably a surfactant having a fluorinated group and a hydrophilic group, and, in this case, the remaining surfactant may not have a fluorinated group.

Specific examples of the surfactant may be perfluoroalkyl group-containing Ftergent M Series, Ftergent F209, Ftergent 222F, Ftergent 208G, Ftergent 218GL, Ftergent 710FL, Ftergent 710FM, Ftergent 710FS, Ftergent 730FL, Ftergent 730LM (manufactured by Neos Company, Limited), Megafac series (manufactured by DIC Corporation) such as Megafac F-553, Megafac F-555, Megafac F-556, Megafac F-557, Megafac F-559, Megafac F-562 and Megafac F-565, Unidyne series (manufactured by Daikin Industries, Ltd.) such as Unidyne DS-403N, etc. Among them, Ftergent 710FL, Ftergent 710FM and Ftergent 710FS manufactured by Neos Company, Limited are preferred, which are surfactants having a steric bulkiness wherein fluorinated groups show branched structures.

As a preferred embodiment of the surfactant in the present invention, a copolymer may be mentioned, of which the main chain is made of a carbon chain derived from an ethylenically unsaturated monomer, and which has a fluorinated hydrocarbon group and a hydrophilic group in the side chain. The fluorinated hydrocarbon group is preferably a group having a tertiary carbon atom to which a plurality (2 or 3) of monovalent fluorinated hydrocarbon groups are bonded.

As a specific example of such a surfactant, a copolymer (but excluding F polymer) comprising units (1) derived from a compound represented by the following formula (1) and units (2) derived from a compound represented by the following formula (2), may be mentioned.

CH₂═CR¹C(O)O—X¹—OC(—Y¹)(—Z¹)₂ (1)

CH₂═CR²C(O)O—X²-Q²-OH (2)

R¹ and R² each independently represent a hydrogen atom or a methyl group.

X¹ and X² each independently represent a C₁₋₆ alkylene group which may contain a hetero atom group, and are preferably —(CH₂)₂—, —(CH₂)₃—, —(CH₂)₄—, —(CH₂)₂NHC(O)—, —(CH₂)₃NHC(O)— or —CH₂CH(CH₃)NHC(O)—.

Y¹ is a hydrogen atom or a fluorine atom.

Z¹ represents a C₁₋₁₀ fluoroalkyl group or a C₂₋₁₀ fluoroalkenyl group which may contain a hetero atom, and is preferably a trifluoromethyl group, a C₂₋₁₀ perfluoroalkenyl group or a C₄₋₁₀ fluoroalkyl group containing an etheric oxygen atom. Two Z¹ may be the same or may be different.

Q² represents a C₄₋₆₀ polyoxyalkylene group, and is preferably a C₄₋₃₀ polyoxyethylene group or a C₆₋₅₀ polyoxypropylene group.

Units (1) are contained preferably in an amount of from 20 to 60 mol %, more preferably in an amount of from 20 to 40 mol %, to all units of the copolymer.

Units (2) are contained preferably in an amount of from 40 to 80 mol %, particularly preferably in an amount of from 60 to 80 mol %, to all units of the copolymer.

The ratio of the content of units (2) to the content of units (1) in the copolymer is preferably from 1 to 5, particularly preferably from 1 to 2.

The copolymer may be composed solely of units (1) and units (2), or may further contain units other than units (1) and units (2).

The fluorine content of the copolymer is preferably from 10 to 45 mass %, particularly preferably from 15 to 40 mass %.

The copolymer is preferably nonionic.

The weight average molecular weight of the copolymer is preferably from 2,000 to 80,000, particularly preferably from 6,000 to 20,000.

Specific examples of the compound (1) may be CH₂═CHCOO(CH₂)₄OCF(CF₃)(C(CF(CF₃)₂)(═C(CF₃)₂), CH₂═CHCOO(CH₂)₄₀C(CF₃)(═C(CF(CF₃)₂)(CF(CF₃)₂), CH₂═C(CH₃)COO(CH₂)₂NHCOOCH(CH₂OCH₂CH₂(CF₂)₆F)₂, CH₂═C(CH₃)COO(CH₂)₂NHCOOCH(CH₂OCH₂CH₂(CF₂)₄F)₂, CH₂═C(CH₃)COO(CH₂)₂NHCOOCH(CH₂OCH₂(CF₂)₆F)₂, CH₂═C(CH₃)COO(CH₂)₂NHCOOCH(CH₂OCH₂(CF₂)₄F)₂, CH₂═C(CH₃)COO(CH₂)₃NHCOOCH(CH₂OCH₂(CF₂)₆F)₂, and CH₂═C(CH₃)COO(CH₂)₃NHCOOCH(CH₂OCH₂(CF₂)₄F)₂.

Specific examples of the compound (2) may be CH₂═CHCOOCH₂CH₂(OCH₂CH₂)₇₀H, CH₂═CHCOOCH₂CH₂(OCH₂CH₂)₉₀H, CH₂═CHCOOCH₂CH₂(OCH₂CH₂)₁₁₀H, CH₂═CHCOOCH₂CH₂CH₂CH₂(OCH₂CH₂)₈₀H, CH₂═CHCOOCH₂CH₂CH₂CH₂(OCH₂CH₂)₁₀OH, CH₂═CHCOOCH₂CH₂CH₂CH₂(OCH₂CH₂)₁₂₀H, CH₂═C(CH₃)COOCH₂CH(CH₃)(OCH₂CH(CH₃))₇₀H, CH₂═C(CH₃)COOCH₂CH(CH₃)(OCH₂CH(CH₃))₁₁₀H, and CH₂═C(CH₃)COOCH₂CH(CH₃)(OCH₂CH(CH₃))₁₅₀H.

The content of the powder in the dispersion of the present invention is preferably from 5 to 50 mass %, more preferably from 15 to 35 mass %, to the total of the organic solvent and the powder. When the content of the powder is at least 5 mass %, the dispersion stability of the dispersion will be further excellent, and it becomes easy to control the thixotropy ratio of the dispersion to be within the predetermined range. When the content of the powder is at most 50 mass %, it becomes easy to control the viscosity of the dispersion to be within the predetermined range.

Further, the dispersion of the present invention preferably contains a surfactant.

In this case, the content of the powder in the dispersion of the present invention is preferably from 35 to 70 mass %, more preferably from 40 to 68 mass %, further preferably from 45 to 65 mass %, still more preferably from 47 to 60 mass %, to the total of the organic solvent, the powder and the surfactant. When the content of the powder is at least 35 mass %, the dispersion will be more excellent in the dispersion stability, and it becomes easy to control the thixotropy ratio of the dispersion to be within the predetermined range. When the content of the powder is at most 70 mass %, it becomes easy to control the viscosity of the dispersion to be within the predetermined range.

In the case of containing a surfactant, the content of the organic solvent in the dispersion of the present invention is preferably from 25 to 60 mass %, more preferably from 27 to 55 mass %, particularly preferably from 30 to 50 mass %, to the total of the organic solvent, the powder and the surfactant. When the content of the organic solvent is within the above range, the dispersion will be further excellent in coating property. When the content of the organic solvent is at most the upper limit value in the above range, poor appearance is less likely to occur in a film or the like produced by using the dispersion. Such poor appearance is often derived from the operation of removing the organic solvent.

The content of the surfactant in the dispersion of the present invention is preferably from 3.5 to 30 mass %, more preferably from 4 to 15 mass %, particularly preferably from 4.5 to 10 mass %, to the total of the organic solvent, the powder and the surfactant. When the content of the surfactant is at least the lower limit value in the above range, the dispersion will be further excellent in dispersibility and dispersion stability. When the content of the surfactant is at most the upper limit value in the above range, the properties of the powder tend to be less influenced by the properties of the surfactant, and it becomes easy to lower the permittivity and dissipation factor of the resin layer containing the powder.

The mass ratio (surfactant/powder) of the content of the surfactant to the content of the powder in the dispersion of the present invention is preferably from 1/99 to 30/70, more preferably from 3/97 to 20/80, particularly preferably from 5/95 to 17/83. When the ratio of the content of the surfactant to the content of the powder is at least the lower limit value in the above range, the dispersion will be further excellent in dispersibility and dispersion stability. When the ratio of the content of the surfactant to the content of the powder is at most the upper limit value in the above range, the properties of the powder tend to be less influenced by the properties of the surfactant, and it becomes easy to lower the permittivity and dissipation factor of the resin layer containing the powder.

In a case where the dispersion of the present invention contains a thixotropic agent, the content of the thixotropic agent is preferably from 0.1 to 20 mass %, particularly preferably from 3 to 10 mass %, to the total of the organic solvent, the powder and the surfactant. In this case, it becomes easy to control the thixotropy ratio and viscosity of the dispersion to be within the predetermined ranges.

In a case where the dispersion of the present invention contains an inorganic filler, the content of the inorganic filler is preferably from 1 to 300 mass %, particularly preferably from 30 to 60 mass %, to the total of the organic solvent, the powder and the surfactant. In this case, the linear expansion coefficient of the film obtainable from the dispersion becomes to be low, and the film will be excellent in thermal dimensional properties and molding stability.

In a case where the dispersion of the present invention contains an antifoaming agent, the content of the antifoaming agent will vary depending on e.g. the content (density) of the powder, etc., but is preferably at most 1 mass % as an active component, to the total amount of the dispersion.

The dispersion of the present invention may contain a thixotropic agent as an optional component. The thixotropic agent may be a clay mineral such as clay, bentonite, hectorite, etc., an emulsion such as a polyester type emulsion resin, an acrylic emulsion resin, a polyurethane type emulsion resin, a blocked isocyanate, etc., a cellulose derivative such as methyl cellulose, carboxymethyl cellulose, hydroxyethyl cellulose, hydroxypropyl cellulose, hydroxypropyl methylcellulose, etc., a polysaccharide such as xanthan gum, guar gum, etc., metal soap, hydrogenated castor oil, polyamide wax, benzylidene sorbitol, amide wax, linseed polymerized oil, modified urea, modified urethane, modified polyether, modified polyester, etc.

The dispersion of the present invention may contain an inorganic filler. The inorganic filler may be a filler described in paragraph [0089] of WO2016/017801. When the dispersion contains an inorganic filler, it will be easy to lower the permittivity and dissipation factor of the resin layer containing the powder.

The dispersion of the present invention may contain an antifoaming agent. The antifoaming agent may be a silicone type antifoaming agent and a fluorosilicone type antifoaming agent. Types of the antifoaming agent may be an emulsion type, a self-emulsifying type, an oil type, an oil compound type, a solution type, a powder type, a solid type, etc.

The method for producing the dispersion of the present invention is not particularly limited, and a method may be mentioned which comprises mixing the organic solvent and the powder preferably together with a surfactant, followed by stirring and dispersing. As the means for mixing and stirring, it is preferred to use a dispersing machine such as a homomixer, a high-speed stirrer, an ultrasonic disperser, a homogenizer, a wet ball mill, a beads mill, a wet jet mill, etc.

The dispersion of the present invention has the viscosity and thixotropy ratio being in the predetermined ranges, and preferably contains a surfactant, whereby it is excellent in mixing property with a varnish and dispersion stability, and therefore, in comparison with the case of handling the powder as a powder, it can be put into a mixing container or the like without scattering the powder.

In particular, with the dispersion, of which the viscosity is at least 100 mPa·s and the thixotropy ratio is from 1.4 to 2.2, the viscosity becomes high under such a condition that the external force is relatively weak, whereby it tends to be easy to form a uniform film without spots, and the coating property tends to be further excellent and further the viscosity can be maintained under such a condition that external force is relatively strong, whereby the dispersibility will be further excellent.

In particular, with the dispersion, of which the viscosity is from 50 to 3,000 mPa·s and the thixotropy ratio is at most 1.5 or less, the viscosity tends to be low under such a condition that the external force is relatively strong; it tends to be easily mixed with a varnish; and in the obtainable mixture, the powder is uniformly dispersed in the varnish, and its coating property will be also excellent.

Further, with the dispersion of the present invention, in a case where D50 and D90 are controlled to be within the specific ranges, in a film or laminate produced by using the dispersion of the present invention, troubles such as reduction of the electrical characteristics and reduction of adhesion to other substrates, due to non-uniformity in dispersion of the powder, tend to be less likely to occur.

As described above, the dispersion of the present invention is excellent in dispersibility and mixing property with a different type of resin material or its varnish. The dispersion of the present invention is preferably mixed further with a different type of resin material (a component not corresponding to the TFE type polymer, the surfactant in the present invention and the above-mentioned components which may be contained in the dispersion of the present invention) or its varnish.

Hereinafter, a solution comprising the dispersion of the present invention, another resin which is a different type of resin material and which is soluble in the after-mentioned vanish solvent (hereinafter referred to also as “another resin”; an organic solvent which dissolves another resin will be referred to also as “a varnish solvent”), and a varnish solvent, will be referred to also as “a coating liquid of the present invention”. The coating liquid of the present invention is obtainable by mixing the dispersion of the present invention, and a varnish containing a second liquid medium and another resin. Further, the dispersion of the present invention and the coating liquid of the present invention may collectively be referred to also as a powder solution of the present invention.

Another resin may be a resin which is soluble in the organic solvent in the present invention, or may be a resin which is insoluble in the organic solvent in the present invention. The latter resin is preferably a resin which is soluble in an organic solvent (hereinafter referred to also as a “varnish solvent”) other than the organic solvent in the present invention.

An embodiment of the coating liquid of the present invention may be an embodiment wherein the dispersion of the present invention and a varnish containing a varnish solvent and another resin, are mixed, or an embodiment wherein a powder of another resin is contained in the dispersion of the present invention, and the powder of the TFE type powder and the powder of another resin are, respectively, dispersed in the organic solvent. In the latter embodiment, another resin is a resin which is insoluble in the organic solvent of the dispersion, and may be a curable resin, a non-curable resin, a heat-fusible resin or a non-fusible resin, which is a resin not soluble in the organic solvent of the dispersion, or a solvent-insoluble liquid crystal polymer.

The solvent-insoluble liquid crystal polymer may be polymers described in paragraphs [0010] to [0015] in JP-A-2000-248056, more specifically, polymers such as a dicarboxylic acid (such as terephthalic acid, etc.), a dihydroxy compound (4,4′-biphenol, etc.), an aromatic hydroxycarboxylic acid (4-hydroxybenzoic acid, 6-hydroxy-2-naphthoic acid, etc.), an aromatic diamine, an aromatic hydroxyamine, an aromatic aminocarboxylic acid, etc., further specifically, a reaction product (polyester) of 4-hydroxy benzoic acid and 6-hydroxy-2-naphthoic acid, a reaction product (polyester) of 6-hydroxy-2-naphthoic acid, terephthalic acid and acetaminophen, and a reaction product (polyester) of 4-hydroxybenzoic acid, terephthalic acid and 4,4′-biphenol.

The varnish solvent may be a compound similar to the organic solvent in the dispersion of the present invention (hereinafter referred to also as “the organic solvent in the present invention”). The varnish solvent may be the same as or different from the organic solvent in the present invention. If the organic solvent in the present invention and the varnish solvent are different, the respective organic solvents may be compatible with each other.

In the dispersion of the present invention, of which the viscosity is from 50 to 3,000 mPa·s and the thixotropy ratio is from 1.0 to 1.5, in the case of selecting a varnish solvent different from the organic solvent in the present invention, it is preferred to select the varnish solvent so that the surface tension of the mixed solvent consisting of the organic solvent in the present invention and the varnish solvent becomes to exceed 30 dyn/cm. It thereby becomes easy to uniformly disperse the powder in the coating liquid.

Another resin may be a curable resin or may be a non-curable resin. Another resin may be a heat meltable resin or may be a non-meltable resin. Otherwise, another resin may be a solvent-soluble liquid crystal polymer.

The curable resin is a resin which will be cured by a reaction between reactive groups of its own or by a reaction with a curing agent. The curable resin may be a polymer, oligomer, low-molecular compound, etc. The reactive groups which the curable resin has, may be carbonyl group-containing groups, hydroxy groups, amino groups, epoxy groups, etc. As the curable resin, a thermosetting resin is preferred.

The thermosetting resin may be an epoxy resin, a thermosetting polyimide, polyamic acid which is a polyimide precursor, an acrylic resin, a phenol resin, a polyester resin, a polyolefin resin, a modified polyphenylene ether resin, a polyfunctional cyanic acid ester resin, a polyfunctional maleimide-cyanic acid ester resin, a polyfunctional maleimide resin, a vinyl ester resin, a urea resin, a diallyl phthalate resin, a melamine resin, a guanamine resin, and a melamine-urea co-condensation resin. From the standpoint of being useful in applications for printed circuit boards, the thermosetting resin is preferably a thermosetting polyimide, a polyimide precursor, an epoxy resin, an acrylic resin, a bismaleimide resin and a polyphenylene ether resin, particularly preferably an epoxy resin and a polyphenylene ether resin.

Specific examples of the epoxy resin may be a naphthalene type epoxy resin, a cresol novolak type epoxy resin, a bisphenol A type epoxy resin, a bisphenol F type epoxy resin, a bisphenol S type epoxy resin, an alicyclic epoxy resin, an aliphatic chain epoxy resin, a cresol novolak type epoxy resin, a phenol novolak type epoxy resin, an alkylphenol novolak type epoxy resin, an aralkyl type epoxy resin, a biphenol type epoxy resin, a dicyclopentadiene type epoxy resin, a trishydroxyphenylmethane type epoxy compound, an epoxidized product of a condensate of phenol and an aromatic aldehyde having a phenolic hydroxy group, a diglycidyl etherified product of bisphenol, a diglycidyl etherified product of naphthalene diol, a diglycidyl etherified product of phenol, a diglycidyl etherified product of an alcohol, a triglycidyl isocyanurate, etc.

The bismaleimide resin may be a resin composition (BT resin) wherein a bisphenol A type cyanic acid ester resin and a bismaleimide compound are used in combination, as described in JP-A-H07-70315, and one as described in the invention and the background art of WO2013/008667.

The polyamic acid usually has a reactive group capable of reacting with an adhesive group.

The diamine and the polyvalent carboxylic acid dianhydride to form a polyamic acid, may, for example, be those disclosed in [0020] of Japanese Patent No. 5766125, in [0019] of Japanese Patent No. 5766125, and in [0055] and [0057] of JP-A-2012-145676. Among them, a combination of an aromatic diamine such as 4,4′-diaminodiphenyl ether or 2,2-bis [4-(4-aminophenoxy)phenyl], and an aromatic polycarboxylic acid dianhydride such as pyromellitic dianhydride, 3,3′,4,4′-biphenyltetracarboxylic acid dianhydride or 3,3′,4,4′-benzophenone tetracarboxylic acid dianhydride, is preferred.

The solvent-soluble liquid crystal polymer may be a polymer comprising units represented by the formula —O—Ar¹—C(O)—, units represented by the formula —C(O)—Ar²—C(O)— and units represented by the formula -L³¹-Ar³-L³²-. In the formulae, Ar¹ represents a 1,2-phenylene group or a 2,6-naphthylene group, Ar² and Ar³ represent each independently a phenylene group, a naphthylene group, a biphenylene group, or a group represented by the formula —Ar⁴¹—Z⁴—Ar⁴²— (wherein Ar⁴¹ and Ar⁴² represent each independently a phenylene group or a naphthylene group, and Z⁴ represents an oxygen atom, a sulfur atom, a carbonyl group, a sulfonyl group or an alkylidene group), and L³¹ and L³² represent each independently an oxygen atom or an imino group. Further, hydrogen atoms in Ar², Ar³, Ar⁴ and Ar⁴² may be each independently substituted by halogen atoms, alkyl groups or aryl groups.

Specific solvent-soluble liquid crystal polymers may be polymers described in paragraphs [0019] to [0042] of JP-A-2010-031256, and more specifically, a reaction product of 2-hydroxy-6-naphthoic acid, isophthalic acid and diphenyl ether-4,4′-dicarboxylic acid, 4-hydroxyacetanilide, and acetic anhydride, may be mentioned.

As the heat-meltable resin, a thermoplastic resin such as a thermoplastic polyimide, and a heat-meltable cured product of a curable resin, may be mentioned.

As the thermoplastic resin, a polyester resin (polyethylene terephthalate, etc.), a polyolefin resin (polyethylene, etc.), a styrene type resin (polystyrene, etc.), a polycarbonate, a thermoplastic polyimide (an aromatic polyimide, etc.), a polyarylate, a polysulfone, a polyallyl sulfone (polyethersulfone, etc.), an aromatic polyamide, an aromatic polyether amide, a polyphenylene sulfide, a polyallyl ether ketone, a polyamideimide, a liquid crystalline polyester, a polyphenylene ether, etc. may be mentioned, and a thermoplastic polyimide, a liquid crystalline polyester and a polyphenylene ether are preferred.

The melting points of the heat-meltable resin and the heat-meltable cured product of a curable resin are preferably at least 280° C. Thus, in a resin layer such as a film made from the coating liquid, it tends to be easy to suppress swelling (bubbling) due to heat when exposed to an atmosphere corresponding to the solder reflow.

The coating liquid of the present invention may contain a curing agent. As the curing agent, a thermosetting agent (a melamine resin, a urethane resin, etc.), an epoxy curing agent (a novolak type phenolic resin, isophthalic acid dihydrazide, adipic acid dihydrazide, etc.), etc. may be mentioned.

The content of the powder in the coating liquid of the present invention is preferably from 1 to 80 mass %, particularly preferably from 10 to 30 mass %, to the total of the organic solvent in the present invention, the powder, the surfactant and another resin and the varnish solvent. When the content of the powder is at least the lower limit value in the above range, the resin layer obtainable by using the coating liquid will be excellent in electrical properties. When the content of the powder is at most the upper limit value in the above range, the powder tends to be uniformly dispersed in the coating liquid, and the resin layer obtainable by using the coating liquid will be excellent in mechanical strength.

The total amount of the organic solvent in the coating liquid of the present invention is preferably from 10 to 80 mass %, more preferably from 20 to 60 mass %, particularly preferably from 30 to 50 mass %, to the total of the organic solvent in the present invention, the powder, the surfactant, another resin and the varnish solvent. When the total amount of the organic solvent is at least the lower limit value in the above range, the viscosity of the coating liquid will be balanced without becoming too high, and the coating property will be further excellent. When the total amount of the organic solvent is at most the upper limit value in the above range, the viscosity of the coating liquid will be balanced without becoming too low; the coating property will be further excellent; and defective appearance of the resin layer obtainable by using the coating liquid will be less likely to occur.

The method for producing the coating liquid of the present invention is not particularly limited, and it may be produced by preliminarily mixing a varnish solvent and another resin to prepare a varnish containing another resin, and mixing the varnish and the dispersion of the present invention.

The powder solution of the present invention can be used for the production of, for example, the later-described film, fiber-reinforced film, prepreg and laminate.

The powder solution of the present invention can also be used in the production of an insulating layer of a flat conductor. For example, at the time of producing an insulating layer composed mainly of any resin among polyamideimide, polyimide and polyester imide, if the powder solution of the present invention is blended to an insulating coating material containing the resin, it is possible to lower the permittivity of the insulating layer. Lowering of the permittivity of the insulating layer can also be achieved by adding the powder in the present invention to the insulating coating material, but from the viewpoint of dispersibility, it is preferred to use the powder solution of the present invention for the insulating coating material. As a specific example of the insulating layer, an insulating coating film as described in JP-A-2013-191356 may be mentioned.

The powder solution of the present invention can also be used in the production of a seamless belt. For example, by using a liquid composition obtained by blending a liquid containing a polyimide resin and a conductive filler, and the powder solution of the present invention, it is possible to obtain a seamless belt excellent in transport properties and cleaning properties for the recording medium (paper). The seamless belt excellent in the transport properties and cleaning properties can also be achieved by adding the powder in the present invention to a liquid containing a polyimide type resin and a conductive filler, but from the viewpoint of dispersibility, it is preferred to use the powder solution of the present invention for the above liquid composition. As the seamless belt, one described in JP-A-2011-240616 may be mentioned.

The present invention also provides a method for producing a film obtainable by film formation by using the powder solution of the present invention, followed by removing the organic solvent. The film formation method is preferably coating on the surface of a support, and by the coating on the support, a film made of the powder solution will be formed. After the film of the powder solution has been formed, the organic solvent is volatilized by a method of e.g. heating the film of the powder solution, whereby a solid film having the organic solvent removed, or a non-flowable film having at least part of the liquid medium removed, will be formed. Here, the removal of the organic solvent is referred to also as “drying”.

In the drying, it is preferred to remove at least 50 mass % out of the organic solvent contained in the powder solution of the present invention. As the drying method, methods as described in [0091] to [0094] of WO2018/16644 may be mentioned.

By separating the film formed on the support from the support, a film is obtainable. By using, as the support, a support having no adhesive surface, it is possible to easily separate the film from the support. Further, in this case, it is preferred to preliminarily apply surface treatment to the support to reduce the adhesiveness. Otherwise, in the case of a support having a highly adhesive surface, the support may be removed by such a means as dissolving the support. For example, in the case of a metallic support, the support may be removed by etching or the like.

Except for the fiber-reinforced film and prepreg as described later, the thickness of the film of the present invention is preferably from 1 to 1,000 μm. For applications to printed boards, the thickness of the film is more preferably from 1 to 100 μm, particularly preferably from 1 to 15 μm.

The relative permittivity of the film of the present invention is preferably from 2.0 to 3.5, particularly preferably from 2.0 to 3.0. When the relative permittivity is within the above range, the film will be excellent in both the electrical properties and fusing properties and will be particularly useful as a laminate such as a metal laminate and a printed board.

The film of the present invention preferably contains at least 80 mass % of the TFE type polymer, to the total amount of the film. In this case, except for the fiber-reinforced film and prepreg as described later, the thermal expansion change ratio and thermal contraction change ratio of the film of the present invention are preferably from 1.0 to 1.4, more preferably from 1.0 to 1.3. When the thermal expansion change ratio or thermal contraction change ratio is within the above range, it is possible to suppress warpage of the laminate.

Here, the thermal expansion change ratio and thermal contraction change ratio can be determined from the respective thermal expansion and thermal shrinkage coefficients, at the time of subjecting the coefficient of thermal expansion or the coefficient of thermal shrinkage in the length direction (MD) and in the direction (TD) perpendicular to MD during the continuous production of the film to a temperature change from 30° C. to 100° C. by using a thermal mechanical analyzer (the measurement mode: tensile mode, the measurement temperature: from 30° C. to 100° C., the measuring load: 19.6 mN, the heating rate: 5° C./min, the measurement atmosphere: nitrogen gas). Specifically, they are obtainable as the ratios of the maximum values among the respective thermal expansion and thermal shrinkage coefficients, to the minimum values among the respective thermal expansion and thermal shrinkage coefficients.

The present invention can provide a fiber-reinforced film by impregnating the powder solution of the present invention to a reinforcing fiber substrate placed on a support, and forming a film, i.e. by drying and then heating.

The form of the reinforcing fiber substrate is preferably a sheet form from the viewpoint of the mechanical properties of the fiber-reinforced film, and preferred is a cloth substrate formed by weaving a reinforcing fiber bundle made of a plurality of reinforcing fibers, a substrate having a plurality of reinforcing fibers drawn in one direction, or a substrate having them stacked.

Reinforcing fibers are preferably continuous long fibers with a length of at least 10 mm. The reinforcing fibers may be divided in the middle.

The reinforcing fibers may be inorganic fibers, metal fibers, organic fibers, etc.

The inorganic fibers may be carbon fibers, graphite fibers, glass fibers, silicon carbide fibers, silicon nitride fibers, alumina fibers, silicon carbide fibers, boron fibers, etc.

The metal fibers may be aluminum fibers, brass fibers, stainless steel fibers, etc.

The organic fibers may be aromatic polyamide fibers, polyaramide fibers, polyparaphenylene benzoxazole (PBO) fibers, polyphenylene sulfide fibers, polyester fibers, acrylic fibers, nylon fibers, polyethylene fibers, etc.

The fiber-reinforced film of the present invention can be used also for the production of metal laminates and printed circuit boards.

The thickness of the fiber-reinforced film is preferably from 1 to 3,000 μm. For applications to printed boards, the thickness of the fiber-reinforced film is more preferably from 3 to 2,000 μm, particularly preferably from 6 to 500 μm.

The relative permittivity of the fiber-reinforced film is preferably from 2.0 to 3.5, particularly preferably from 2.0 to 3.0. When the relative permittivity is within the above range, both the electrical properties and the fusing properties for applications to printed boards tend to be readily satisfied.

The present invention can provide also a prepreg by impregnating the powder solution of the present invention to a reinforcing fiber substrate disposed on a support, followed by drying. The production of a prepreg is similar to the production of a fiber-reinforced film, except that heating after the drying is not carried out, or no adequate heating is conducted. That is, the prepreg contains reinforcing fibers and a non-melted (or not sufficiently melted) powder, and it can be said to be a film containing an uncured curable resin as the case requires.

In the production of the prepreg, it is preferred to impregnate the coating liquid of the present invention to the reinforcing fiber substrate. The coating liquid in this case preferably contains an uncured curable resin.

In the drying in the production of a prepreg, the liquid medium may be left. In the production of a prepreg, it is preferred to remove at least 70 mass %, out of the total amount of the organic solvent contained in the coating liquid of the present invention.

The prepreg can be used as a molding material, and it can be used to produce metal laminates and printed boards. Further, the prepreg of the present invention can be used as a material for sheet piles which are required to have durability and light weight for quay construction, and as a material for producing a member for a variety of applications, such as aircrafts, automobiles, ships, wind turbines, sports equipment.

The relative permittivity of the prepreg is preferably from 2.0 to 4.0, particularly preferably from 2.0 to 3.5. When the relative permittivity is within the above range, both the electric properties and the fusing properties for applications to printed boards tend to be readily satisfied.

In the method for producing a laminate of the present invention, it is possible to provide also a method for producing a laminate having a resin layer on the surface of a substrate, which comprises forming a film on a substrate by using the powder solution of the present invention, and removing the organic solvent to provide a resin layer containing a TFE type polymer on the substrate. In other words, the method for producing a laminate of the present invention corresponds to a method for obtaining a laminate having a film and a support without separating the film and the support, in the above-described method for producing a film. That is, the substrate corresponds to the support; the resin layer corresponds to the film; and the substrate having the resin layer on the surface corresponds to the laminate. The resin layer may be a fiber-reinforced film or may be a prepreg.

The substrate is not particularly limited and may be a metal film, a heat-resistant resin film, a metal vapor deposited heat-resistant resin film, and preferred is a metal film (metal foil).

As the metal constituting the metal film (metal foil), copper or its alloy, stainless steel or its alloy, titanium or its alloy, etc. may be mentioned. As the metal film (metal foil), a copper film (copper foil) such as a rolled copper foil, or an electrolytic copper foil, is preferred. On the surface of the metal film (metal foil), an anticorrosive layer (e.g. an oxide film of e.g. zinc chromate, etc.), a heat-resistant layer, or a barrier layer (a coating film of nickel, cobalt, etc.) may be provided. Such a layer may be formed by plating treatment or may be formed by chemical conversion treatment. Further, in order to improve the adhesion to the resin layer, the surface of a metal film (metal foil) may be treated with a silane coupling agent. The thickness of the metal film (metal foil) is not particularly limited.

The metal vapor deposited heat-resistant resin film may be a film having a metal vapor deposited on one or both sides of the later-described heat-resistant resin film by a vacuum deposition method, such as a vacuum vapor deposition method, a sputtering method, an ion plating method, etc.

The ten-point average roughness (Rzⱼᵢₛ value defined by JIS B0601: 2001) of the surface of the metal film (metal foil) is preferably from 0.3 to 2.0 μm, particularly preferably from 0.5 to 1.8 μm.

The silane coupling agent may be epoxysilane, aminosilane, vinylsilane, acryloxy silane, methacryloxy silane, ureido silane, mercapto silane, sulfide silane, or isocyanate silane. As the silane coupling agent, one type may be used alone, or two or more types may be used in combination.

The heat-resistant resin film is a film containing at least one heat-resistant resin. However, the heat-resistant resin film does not contain a TFE type polymer. The heat-resistant resin film may be a monolayer film or a multilayer film. Here, the heat-resistant resin means a polymeric compound having a melting point of at least 280° C., or a polymeric compound, of which the maximum continuous use temperature defined by JIS C4003: 2010 (IEC 60085: 2007) is at least 121° C. As the heat-resistant resin, for example, a polyimide (an aromatic polyimide, etc.), a polyarylate, a polysulfone, a polyallyl sulfone (a polyether sulfone etc.), an aromatic polyamide, an aromatic polyether amide, a polyphenylene sulfide, a polyallyl ether ketone, a polyamideimide, a liquid crystal polyester, etc. may be mentioned.

As the heat-resistant resin film, a polyimide film and a liquid crystal polyester film are preferred. The polyimide film may contain additives, as the case requires, within a range not to impair the effects of the present invention. The heat-resistant resin film may be subjected to surface treatment such as corona discharge treatment or plasma treatment, at the surface on which a resin layer will be provided. As the heat-resistant resin film, more preferred is a liquid crystal polyester film from the viewpoint of excellent electrical properties.

In the method for producing a laminate of the present invention, a resin layer may be provided only on one side in the thickness direction of the substrate, or it may be provided on both sides. From such a viewpoint that it will be easy to suppress warpage of the laminate, and it will be easy to obtain a metal laminate having excellent electrical reliability, it is preferred to provide a resin layer on both sides of the substrate. In this case, it is preferred that on one side of the substrate, the powder solution of the present invention is applied and dried, and then, on the other surface, the powder solution of the present invention is applied and dried.

With the powder solution of the present invention, the viscosity and thixotropy ratio are within the predetermined ranges, whereby it is suitable for forming a resin layer having an optional thickness, especially of a thick film (particularly a film thickness of at least 1 μm), excellent in nature such as surface smoothness.

The thickness of the resin layer of the laminate of the present invention is, in a case where the filler contained in the resin layer is less than 10 vol %, preferably from 0.5 to 30 μm. For applications to printed boards, the thickness of the resin layer is more preferably from 0.5 to 25 μm, further preferably from 1 to 20 μm, particularly preferably from 3 to 15 μm, especially preferably from 3 to 10 μm. In the preferred ranges, warpage of the laminate is suppressed. In a case where the filler contained in the resin layer is at least 10 vol %, from 0.5 to 3,000 μm is preferred. For applications to printed boards, the thickness of the resin layer is more preferably from 1 to 1,500 μm, particularly preferably from 2 to 100 μm.

In the case of a laminate having resin layers on both sides of the substrate, with a view to suppressing warpage of the laminate, it is preferred to adjust that the compositions and thicknesses of the respective resin layers will be the same.

The warpage rate of the laminate of the present invention is preferably at most 25%, more preferably at most 15%, further preferably at most 10%, particularly preferably at most 7%. In such a case, handling efficiency will be excellent in the molding process at the time of processing, and the processed product will be excellent in dielectric properties.

In a case where the powder solution of the present invention contains an inorganic filler, or contains a polychlorotrifluoroethylene, etc., it is possible to further suppress warpage of the laminate.

The relative permittivity of the resin layer of the laminate of the present invention is preferably from 2.0 to 3.5, particularly preferably from 2.0 to 3.0. When the relative permittivity is at most the upper limit value in the above range, such is useful in applications where a low permittivity is required, such as in application for printed boards. When the relative permittivity is at least the lower limit value in the above range, the laminate will be excellent in electrical properties and fusing properties. In a case where the substrate is made of a non-conductive material such as a heat-resistant resin, the relative permittivity of the entire laminate is also preferably within the above range.

An object to be laminated, may be laminated on the surface of the resin layer which the laminate of the present invention has. In such a case, a film or laminate produced by the method of the present invention may be applied as the object to be laminated.

At the time of laminating the object to be laminated on the surface of the resin layer, the substrate surface or the resin layer surface which the object to be laminated has, is laminated on the exposed surface of the resin layer. When laminating the resin layers, lamination may be made by interposing an object to be laminated, such as a prepreg, between the resin layer surfaces.

At the time of laminating an object to be laminated, such as film, sheet, etc., on the surface of a resin layer of the laminate, it is preferred to make the exposed surface of the resin layer to be a highly smooth surface, so that the obtainable laminate will be excellent in bonding strength, and air bubbles will be less likely to remain. In order to increase the smoothness of the exposed surface of the resin layer, it is preferred to conduct lamination at a temperature at which the film after drying will be sufficiently melted, and at the same time to conduct pressing by means of a heating plate, heating roll or the like.

The arithmetic average roughness Ra of the surface of the exposed surface of the resin layer of the laminate is less than the thickness of the resin layer, preferably at least 2.0 μm. Thus, when an object to be laminated is laminated by e.g. hot pressing, adhesion between the resin layer and the object to be laminated will be further excellent.

The above Ra is less than the thickness of the resin layer, and is preferably from 2.0 to 30 μm, most preferably from 2.2 to 8 μm. In such a case, not only adhesion between the resin layer and the object to be laminated will be excellent, but also through holes will be less likely to be formed. Further, in order to increase the bonding strength, surface treatment such as corona discharge treatment, plasma treatment or the like, may be applied to the surface of the resin layer.

The film or laminate of the present invention can be used in an application to produce a new laminate by laminating it to an object to be laminated in the form of a film or sheet made of a material other than metal. The object to be laminated may be a film or sheet of a heat-resistant resin, a fiber-reinforced resin sheet, prepreg or the like.

The prepreg may be one having a matrix resin impregnated in a sheet-like reinforcing fiber substrate.

The matrix resin may be a thermoplastic resin, or a thermosetting resin. The present invention is particularly effective when, as the matrix resin, a thermoplastic resin having a melting point of at most 280° C. or a thermosetting resin having a thermosetting temperature of at most 280° C., is used, from the viewpoint of low-temperature bonding.

As the prepreg, a commercially available prepreg may be used.

As the commercially available prepreg, prepregs described in [0133] of WO2018/16644 may be mentioned.

The temperature at the time of hot pressing the film or laminate of the present invention and the prepreg, is preferably at most the melting point of the TFE type polymer, more preferably from 120 to 300° C. In this case, while suppressing the thermal deterioration of the prepreg, it is possible to bond the film or laminate and the prepreg with excellent adhesion.

The film and laminate obtainable by the production method of the present invention may also be used as a coated article such as a capture substrate of an organic EL display, as described in [0040] to [0044] of WO2015/182702. The prepreg of the present invention may also be used for FRP or CFRP as described in [0046] of WO2015/182702. Further, the powder solution of the present invention may also be used as a solvent type coating material, as described in WO2015/182702, and as an insulating coating material for forming an insulating layer of an insulated wire as described in Japanese Patent No. 2686148.

The present invention can also provide a method for producing a metal laminate, which comprises producing a film (including a fiber-reinforced film and a film of prepreg) by the method for producing a film of the present invention, and providing a metal layer on the surface of the film. Further, in the method for producing a metal laminate of the present invention, a laminate may be produced by the method for producing a laminate of the present invention, and a metal layer may be provided on the surface of the resin layer of the laminate.

As a method of providing a metal layer on one or both sides of the film or laminate, for example, a method of laminating a film or laminate and a metal foil, or a method of vapor depositing a metal on the surface of the resin layer of the film or laminate, may be mentioned. As the lamination method, for example, heat lamination may be mentioned. As the method of vapor depositing a metal, a vacuum vapor deposition method, a sputtering method, an ion plating method, etc. may be mentioned.

As the layer structure of the metal laminate, a laminate of a film of the present invention/metal layer, a metal layer/film of the present invention/metal layer, a laminate layer of the present invention/metal layer, or a metal layer/laminate layer of the present invention/metal layer, may be mentioned. However, the layer in the laminate in contact with the metal layer is a resin layer. Here, the “film/metal layer” means that a film and a metal layer are laminated in this order, and the same applies to other layer structures.

The metal laminate obtainable by the production method of the present invention has a resin layer on one or both sides of a metal layer. As the metal layer, a copper foil is particularly preferred. The resin layer may have reinforcing fibers, or may be a layer of a prepreg (i.e. a resin layer containing reinforcing fibers and an uncured curable resin).

The metal laminate having a copper foil layer may be a metal laminate having a plurality of such a metal laminate laminated to have a plurality of copper foil layers. In a case where the metal laminate having these copper foil layers has a resin layer on one or both sides, it is preferable to laminate a copper foil layer on the surface of the resin layer. The metal laminate having a copper foil layer obtainable by the method for producing a metal laminate of the present invention, and a laminate thereof, may be used as a flexible copper-clad laminate or a rigid copper-clad laminate.

Hereinafter, taking the metal laminate having a copper foil layer as an example, the method for producing a metal laminate of the present invention will be further described.

The metal laminate having a copper foil layer is produced by using a copper foil as the substrate, applying the powder solution of the present invention on one side of the copper foil to form its film, followed by heating and drying to remove the organic solvent, continuously heating to melt the powder, followed by cooling, and is preferably produced as a metal laminate having a uniform resin layer with no unmelted particles. It may be produced by providing resin layers on both sides of the copper foil.

The film formation from the powder solution of the present invention, heating and drying, and melting of the powder can be conducted under the same conditions as in the method of producing a film. For example, in the case where the heating after drying is conducted by heating by means of a heat roll, a metal laminate having a non-molten resin layer and a copper foil layer after drying, is brought into contact with a heat-resistant roll, and transported while being irradiated with far infrared rays, to form a resin layer having the non-molten resin layer melted. The conveying speed of the roll is preferably from 4.7 to 0.31 m/min in the case of using a heating furnace with a length of 4.7 m, and preferably from 4.7 to 2.45 m/min in the case of using a heating furnace with a length of 2.45 m. The heating temperature is, if the residence time in the heating furnace is 1 minute, preferably from 330 to 380° C., more preferably from 350 to 370° C.

The thickness of the resin layer of the metal laminate is preferably at most 15 μm, more preferably at most 10 μm, particularly preferably at most 8 μm. The lower limit is not particularly limited, and is 1 μm. At most the upper limit value in the above range, warpage can be suppressed even in the case of an asymmetric layer structure of the resin layer/copper foil. The warpage rate of the metal laminate is preferably at most 25%, particularly preferably at most 7%. When the warpage rate is at most 25%, handling efficiency will be excellent in the molding process at the time of processing to a printed board, and dielectric properties as a printed board will be excellent.

In a case where the powder solution of the present invention contains a thermosetting resin, it is possible to produce a metal laminate having a resin layer containing a cured thermoset resin and a copper foil layer. In this case, the powder solution of the present invention may contain a filler, and a fiber-reinforced resin layer may be provided on the copper foil layer by using reinforcing fibers. The thickness of the resin layer in this case is preferably at most 200 μm, more preferably at most 100 μm. In such a case, a printed board produced from the powder solution of the present invention will be excellent in processability in hole drilling, and it will be possible to form an electronic circuit excellent in connection reliability. Also, if the resin layer contains a filler, it will be possible to further suppress warpage.

In the production of a metal laminate, it is possible to reduce the linear expansion coefficient in the thickness direction by annealing. It is thereby possible to reduce peeling at an interface between the substrate and the resin layer and to reduce variations in electrical properties of the substrate by unevenness in the thickness in plane of the metal laminate.

As an annealing condition, the temperature is preferably from 80 to 190° C., particularly preferably from 120 to 180° C. The treating time is preferably from 10 to 300 min, particularly preferably from 30 to 120 min. In such a case, while suppressing the thermal deterioration of the resin layer, it is readily possible to reduce the linear expansion coefficient.

The pressure for annealing is preferably from 0.001 to 0.030 MPa, particularly preferably from 0.005 to 0.015 MPa. In such a case, while suppressing the compression of the substrate, it is readily possible to reduce the linear expansion coefficient of the resin layer.

In the method for producing a metal laminate of the present invention, it is possible to produce a metal laminate having a titanium foil and a resin layer, for example, by providing a resin layer on one side or both sides of the titanium foil. The thickness of the resin layer is preferably at most 10 μm. By laminating a fiber-reinforced composite material to the resin layer side of such a metal laminate, it is possible to obtain a metal laminate of e.g. titanium foil/resin layer/fiber-reinforced composite material. As the fiber-reinforced composite material, a carbon fiber-reinforced composite material is particularly preferred.

As the layer structure of the metal laminate having the resin layer and the object to be laminated, a laminate of a metal layer/resin layer/object to be laminated/resin layer/metal layer, or a laminate of a metal layer/object to be laminated/resin layer/object to be laminated/metal layer, may be mentioned. The thickness of the resin layer is preferably from 0.1 to 300 μm, particularly preferably from 2 to 40 μm. In such a case, not only drilling processability is good and dielectric properties are excellent as a metal laminate, but also it is possible to bond the metal layer and the resin layer, and the object to be laminated and the resin layer, with excellent adhesion. The adhesion (peel strength) between the film or laminate produced by the production method of the present invention, and the object to be laminated, is preferably at least 5 N/cm, particularly preferably at least 7 N/cm.

The present invention can also provide a method for producing a printed board, which comprises producing a metal laminate by the production method of a metal laminate of the present invention, and etching the metal layer of the metal laminate to form a patterned circuit. As the method for producing a printed board, for example, a method of forming a patterned circuit by etching the metal layer of the metal laminate obtained by the production method of the present invention, may be mentioned. The method of etching the metal layer is not particularly limited.

In the method for producing a printed board of the present invention, after forming a patterned circuit by etching the metal layer, an interlayer insulating film may be formed on the patterned circuit, and a patterned circuit may further be formed on the interlayer insulating film. The interlayer insulating film may also be formed by the powder solution of the present invention.

For example, after forming a patterned circuit by etching the metal layer of the metal laminate having an optional laminated structure, the powder solution of the present invention is applied on the patterned circuit, followed by heating and drying to form an interlayer insulating film. Then, a metal layer is formed by e.g. vapor deposition on the interlayer insulating film, followed by etching to form an additional patterned circuit.

In the production of the printed board, a solder resist may be laminated on the patterned circuit. Specifically, the dispersion or the coating liquid of the present invention may be applied on the patterned circuit, dried and then heated to form a solder resist.

In the production of a printed board, a coverlay film may be laminated. A coverlay film is typically composed of a substrate film and an adhesive layer provided on the surface thereof, and the surface on the adhesive layer side is bonded to the printed board. As the coverlay film, for example, the film of the present invention may be used. Further, on a patterned circuit formed by etching the metal layer of the metal laminate, an interlayer insulating film using a film obtained by the production method of the present invention may be formed, and on the interlayer insulating film, a polyimide film may be laminated as a cover lay film.

The printed board of the present invention is useful as a substrate for electronic equipment, such as a radar required to have high-frequency characteristics, network routers, backplanes, wireless infrastructures, etc., as a substrate for various automotive sensors, and as a substrate for an engine management sensor, and it is particularly suitable for applications for the purpose of reducing a transmission loss in the millimeter wave band. Further, the printed board of the present invention is useful also in applications such as a high heat dissipation substrate, an antenna substrate, a signal transmission substrate, etc.

As an insulated wire, an insulated wire may be mentioned wherein using the powder solution of the present invention, an insulating covering layer having a thickness of from 10 to 150 μm is formed on the outer periphery of a flat wire. The relative permittivity of the insulating covering layer is preferably at most 2.8. The adhesion strength between the insulating covering layer and the metal species used in the flat wire is preferably at least 10 N/cm. The insulated wire is suitable for any of devices such as an insulation amplifier, an isolation transformer, an automotive alternator and a motor of a hybrid vehicle. Further, the powder solution of the present invention may be used also for a loudspeaker diaphragm, a copper wire covering material, an inorganic fiber cloth impregnated material, etc.

### EXAMPLES

In the following, the present invention will be described in detail with reference to Examples, but the present invention is not limited thereto.

The abbreviations have the following meanings.

TEE: tetrafluoroethylene.

NAH: Nadic anhydride.

PPVE: perfluoro(propyl vinyl ether).

a₁: the proportion of the powder to the total of the organic solvent, the powder and the surfactant.

a₂: the proportion of the surfactant to the total of the organic solvent, the powder and the surfactant.

a₃: the proportion of the organic solvent to the total of the organic solvent, the powder and the surfactant.

b₁: the ratio of the proportion of the surfactant to the proportion of the powder (a₂/a₁).

η₁: the viscosity measured under the condition of a rotational speed of 30 rpm.

η₂: the viscosity measured under the condition of a rotational speed of 60 rpm.

η₁/η₂: the thixotropy ratio.

The materials used, are shown below.

### <TFE Type Polymer>

Polymer 1: a copolymer comprising units derived from TFE, units derived from NAH and units derived from PPVE in amounts of 97.9 mol %, 0.1 mol % and 2.0 mol % in this order, and a polymer, of which the melting point is 300° C. and the melt viscosity at 300° C. is 10³.

Polymer 2: a substantially homopolymer of TFE containing at least 99.5 mol % of units derived from TFE (manufactured by Asahi Glass Company, Limited, L169J).

Polymer 3: a polymer having a melt viscosity at 380° C. of 1×10⁴, obtainable by plasma treating a substantially homopolymer of TFE containing at least 99.5 mol % of units derived from TFE.

Polymer 4: a copolymer comprising units derived from TFE and units derived from PPVE in amounts of 98.0 mol % and 2.0 mol % in this order, and a polymer, of which the melting point is 305° C. and the melt viscosity at 380° C. is 3×10⁵ Pa·s.

Polymer 5: a copolymer comprising units derived from TFE and units derived from HFP in amounts of 88.0 mol % and 12.0 mol % in this order, and a polymer, of which the melting point is 270° C. and the melt viscosity at 380° C. is 2×10⁵ Pa·s.

Polymer 6: a polymer having a melt viscosity at 380° C. of 3×10⁴ obtainable by radiation treating a substantially homopolymer of TFE containing at least 99.5 mol % of units derived from TFE.

Polymer 7: a substantially homopolymer of TFE containing at least 99.5 mol % of units derived from TFE, and a polymer having a melt viscosity at 380° C. of 1×10⁹.

### <Surfactant>

Compound 1: a poly(meth)acrylate polymer having a —OCF(CF₃)C(═C(CF₃)₂)(CF(CF₃)₂) group and a polyoxyethylene group (nonionic surfactant, manufactured by Neos Company, Limited, Ftergent 710FL).

Compound 2: a poly(meth)acrylate polymer having a —OCF(CF₃)C(═C(CF₃)₂)(CF(CF₃)₂) group and a polyoxyethylene group (nonionic surfactant, manufactured by Neos Company, Limited, Ftergent 710FM).

Compound 3: a poly(meth)acrylate polymer having a —(CF₂)₆F group and having no hydrophilic group.

Compound 4: a nonionic surfactant having a polyoxyethylene group and having no fluorinated hydrocarbon group (manufactured by Showa Chemical Co., Ltd., TRITON X-100).

### <Organic Solvent>

MEK: methyl ethyl ketone (surface tension: 24 dyn/cm).

Tol: toluene (surface tension: 28.5 dyn/cm).

CHN: cyclohexanone (surface tension: 34 dyn/cm).

MEK & CHN: a mixed solvent of 70 mass % of MEK and 30 mass % of CHN (surface tension: 27 dyn/cm).

DMF: dimethylformamide (surface tension: 33.5 dyn/cm).

DMAc: N,N-dimethylacetamide

NMP: N-methyl-2-pyrrolidone.

### <Powder>

Powder X1: a powder of polymer 1, of which D50 is 1.7 μm, D90 is 3.8 μm, the loose packing bulk density is 0.269 g/mL, and the packed bulk density is 0.315 g/mL. Obtainable by pulverizing pellets (particle size: 1,554 μm) of polymer 1 twice by using a jet mill and further classifying them by using a high efficiency precision air classifier.

Powder X2: a powder of polymer 2, of which D50 is 3.0 μm, D90 is 8.5 μm, the loose packing bulk density is 0.355 g/mL and the packed bulk density is 0.387 g/mL. Obtainable by pulverizing pellets of polymer 2.

Powder X3: a powder of polymer 3, of which D50 is 0.3 μm and D90 is 0.5 μm.

Powder X4: a powder of polymer 4, of which D50 is 1.8 μm and D90 is 6.2 μm.

Powder X5: a powder of polymer 5, of which D50 is 0.4 μm and D90 is 1.2 μm.

Powder X6: a powder of polymer 6, of which D50 is 0.8 μm and D90 is 1.7 μm.

Powder X7: a powder of polymer 7, of which D50 is 3.0 μm and D90 is 8.0 μm.

The analysis conditions are shown below.

### <D50 and D90 of the Powder>

By dispersing the powder of the polymer in water, measured by using a laser diffraction scattering type particle size distribution measuring apparatus (manufactured by HORIBA, Ltd., LA-920 instrument).

### <Melt Viscosity of the Polymer>

In accordance with ASTM D1238, using a flow tester and a 2ϕ-8L die, measured by maintaining a polymer sample (2 g) preliminarily heated at the measuring temperature for 5 minutes, at the measuring temperature under a load of 0.7 MPa.

### <Viscosity of the Dispersion>

By means of the B type viscometer (LVDV2T model, manufactured by Brookfield), measured under the conditions of a temperature of 25° C. and a rotational speed of 30 rpm.

### <Surface Tension of the Organic Solvent>

Measured by means of a tensiometer (DY-200 Model, manufactured by Kyowa Interface Science Co., Ltd.).

### <Dispersion Stability of the Dispersion>

With respect to the dispersion, the dispersion state after being left to stand for 3 days was visually observed and evaluated according to the following standards.

1: The powder is settled, and it is not possible to re-disperse it even by shaking (hard caking).

2: Sedimentation of the powder is confirmed, but re-dispersion is possible by shaking.

3: Sedimentation of the powder is slightly confirmed, but re-dispersion is possible by shaking.

### <Low-Temperature Dispersion Stability of the Dispersion>

With respect to the dispersion, the dispersion state after being left to stand for 1 day at −5° C. was visually observed, and evaluated according to the following standards.

1: The powder is settled, and it is not possible to re-distribute it even by shaking (hard caking).

2: Sedimentation of the powder is confirmed, but it is possible to re-disperse it by shaking.

### <Coating Property of the Dispersion>

By using the dispersion, coating was conducted by film-formation on a copper foil by a wire bar (manufactured by Tester Sangyo Co., Ltd., No14). After the coating, the organic solvent was dried and removed at a temperature lower by 5° C. than the boiling point of the organic solvent, to obtain a test piece having a resin layer provided on the copper foil. If coated uniformly, the film thickness of the test piece is about 50 μm. In the test piece after drying the organic solvent, the resin layer containing the powder is laminated to be visually observed as a white layer. However, there are coating spots, and if the thickness is thin, the color of the copper foil of the substrate is visible, whereby shading occurs in the white degree, and the presence or absence of the coating spots can be visually judged. The test piece was visually observed to evaluate the coating property under the following standards.

1: The powder layer on the substrate is unevenly applied, whereby there are shades in appearance of the powder layer, or the color of the substrate is visible.

2: The powder layer on the substrate is uniformly applied, whereby there are little shades in appearance of the powder layer.

### <Film Properties>

By using the coating liquid, a film was formed on a copper foil substrate by a wire bar, and dried at 180° C. for 7 minutes in an oven. The permittivity of the obtained film was measured, and the film properties were evaluated by the following standards.

1: The permittivity of the film is varied from 3.2 being the reference value.

2: The permittivity of the film is not varied from 3.2 being the reference value.

### [Ex. 1]

To 450 g of powder X1, 50 g of compound 1 and 500 g of MEK were charged into a lateral ball mill container, and by using zirconia balls with a diameter of 15 mm, a dispersion in Ex. 1 was obtained. The viscosity of the dispersion in Ex. 1 was such that η₁ was 250 mPa·s and η₂ was 150 mPa·s, and the thixotropy ratio was 1.7. With respect to the dispersion in Ex. 1, dispersion stability and coating property were evaluated. The results are shown in Table 2.

### [Ex. 2 to 10]

A dispersion was obtained in the same manner as in Ex.1, except for changing the composition ratio as shown in Table 1. With respect to the obtained dispersion, η₁ and η₂ were measured, the thixotropy ratio was calculated, and dispersion stability and coating property were evaluated. The results are shown in Table 2.

TABLE 1

| | | | | a₁ | a₂ | a₃ | b₁ |
|---|---|---|---|---|---|---|---|
| | Powder | Surfactant | Solvent | [mass %] | [mass %] | [mass %] | [%] |
| Ex. 1 | X1 | Compound 1 | MEK | 45 | 5 | 50 | 11.1 |
| Ex. 2 | X1 | Compound 1 | MEK | 50 | 5 | 45 | 10.0 |
| Ex. 3 | X1 | Compound 1 | MEK | 40 | 4 | 56 | 10.0 |
| Ex. 4 | X1 | Compound 1 | Tol | 50 | 5 | 45 | 10.0 |
| Ex. 5 | X1 | Compound 1 | Tol | 55 | 8 | 37 | 14.5 |
| Ex. 6 | X1 | Compound 1 | MEK&CHN | 50 | 5 | 45 | 10.0 |
| Ex. 7 | X1 | Compound 1 | MEK | 33 | 3.3 | 63.7 | 10.0 |
| Ex. 8 | X2 | Compound 1 | MEK | 45 | 5 | 50 | 11.1 |
| Ex. 9 | X1 | Compound 3 | MEK | 45 | 5 | 50 | 11.1 |
| Ex. 10 | X1 | Compound 1 | CHN | 40 | 4 | 56 | 10.0 |

TABLE 2

| | η₁ | η₂ | η₁/η₂ | Dispersion | Coating |
|---|---|---|---|---|---|
| | [mPa · s] | [mPa · s] | [—] | stability | property |
| Ex. 1 | 250 | 150 | 1.7 | 3 | 2 |
| Ex. 2 | 430 | 220 | 2.0 | 3 | 2 |
| Ex. 3 | 190 | 130 | 1.5 | 2 | 2 |
| Ex. 4 | 390 | 260 | 1.5 | 3 | 2 |
| Ex. 5 | 500 | 320 | 1.6 | 3 | 2 |
| Ex. 6 | 200 | 130 | 1.5 | 2 | 2 |
| Ex. 7 | 13 | 13 | 1.0 | 2 | 1 |
| Ex. 8 | 16 | 16 | 1.0 | 1 | 1 |
| Ex. 9 | 30,000 | 33,000 | 0.9 | — | — |
| Ex. 10 | 42 | 38 | 1.1 | 2 | 1 |

### [Ex. 11]

To 500 g of powder X1, 50 g of compound 2 and 450 g of CHN were charged into a lateral ball mill container, and by using zirconia balls with a diameter of 15 mm, a dispersion was obtained. The viscosity of the dispersion was such that η₁ was 150 mPa·s and η₂ was 130 mPa·s, and the thixotropy ratio was 1.2. The dispersion stability of the obtained dispersion was “3”.

Then, the main agent of an epoxy resin (manufactured by DIC Corporation, EPICLON HP-7200H-75M, solvent: MEK, solid content: 75 mass %) and a curing agent for epoxy resin (manufactured by DIC Corporation, Phenolite TD-2090-60M, solvent: MEK, solid content: 60 mass %) were mixed so that the solid content of the main agent:solid content in the curing agent would be 26:9 (mass ratio), to prepare an epoxy varnish containing an epoxy resin. The solid content concentration of the epoxy varnish was 70 mass %. Then, the epoxy varnish and the dispersion were mixed so that the solid content in the epoxy varnish:powder would be 70:30 (mass ratio). The mixing was conducted by stirring for 5 minutes under a condition of 1,000 rpm by a stirrer. The viscosity of the obtained powder-containing varnish (coating liquid) was 520 mPa·s. Further, the surface tension of the organic solvent in the coating liquid was 28 dyn/cm.

Then, the permittivity of the film obtainable by using the coating liquid was measured, and the film properties were evaluated.

### [Ex. 12 to 21]

A dispersion was obtained in the same manner as in Ex. 11 except for changing the composition ratio as shown in Table 3. With respect to each dispersion, η₁ and η₂ were measured, the thixotropy ratio was calculated, and dispersion stability was evaluated.

Then, in the same manner as in Ex. 11, each dispersion and the epoxy varnish were mixed to obtain a powder-containing varnish (coating liquid). By using each coating liquid, a film was produced, and the film properties were evaluated. The results are shown in Table 4.

TABLE 3

| | | | | a₁ | a₂ | a₃ | b₁ |
|---|---|---|---|---|---|---|---|
| | Powder | Surfactant | Solvent | [mass %] | [mass %] | [mass %] | [%] |
| Ex. 11 | X1 | Compound 2 | CHN | 50 | 5 | 45 | 10.0 |
| Ex. 12 | X1 | Compound 2 | CHN | 60 | 6 | 34 | 10.0 |
| Ex. 13 | X1 | Compound 2 | CHN | 40 | 4 | 56 | 10.0 |
| Ex. 14 | X1 | Compound 1 | CHN | 50 | 5 | 45 | 10.0 |
| Ex. 15 | X1 | Compound 1 | CHN | 55 | 5.5 | 39.5 | 10.0 |
| Ex. 16 | X1 | Compound 1 | CHN | 55 | 8.2 | 36.8 | 14.9 |
| Ex. 17 | X1 | Compound 2 | DMF | 33.1 | 2.5 | 64.4 | 7.6 |
| Ex. 18 | X2 | Compound 2 | CHN | 33.1 | 2.5 | 64.4 | 7.6 |
| Ex. 19 | X1 | Compound 2 | CHN | 33.1 | 2.5 | 64.4 | 7.6 |
| Ex. 20 | X1 | Compound 2 | CHN | 70 | 7 | 23 | 10.0 |
| Ex. 21 | X1 | Compound 4 | CHN | 40 | 4 | 56 | 10.0 |

TABLE 4

| | | | | | Viscosity of | | |
|---|---|---|---|---|---|---|---|
| | η₁ | η₂ | η₁/η₂ | Dispersion | coating liquid | Film | |
| | [mPa · s] | [mPa · s] | [—] | stability | [mPa · s] | properties | Permittivity |
| Ex. 11 | 150 | 130 | 1.2 | 3 | 520 | 2 | 3.2 |
| Ex. 12 | 340 | 270 | 1.3 | 3 | — | 2 | 3.2 |
| Ex. 13 | 130 | 110 | 1.2 | 2 | — | 2 | 3.2 |
| Ex. 14 | 210 | 190 | 1.1 | 3 | — | 2 | 3.2 |
| Ex. 15 | 270 | 250 | 1.1 | 3 | — | 2 | 3.2 |
| Ex. 16 | 190 | 170 | 1.1 | 2 | — | 2 | 3.2 |
| Ex. 17 | 10 | 10 | 1.0 | 2 | 285 | 1 | 3.4 |
| Ex. 18 | 10 | 10 | 1.0 | 1 | 270 | 1 | 3.3 |
| Ex. 19 | 10 | 10 | 1.0 | 2 | — | 1 | 3.3 |
| Ex. 20 | 42,100 | 21,300 | 2.0 | — | — | — | — |
| Ex. 21 | 47,000 | 27,500 | 1.7 | — | — | — | — |

### [Ex. 22]

To 450 g of powder X3, 50 g of compound 1 and 500 g of MEK were charged into a lateral ball mill container, and by using zirconia balls with a diameter of 15 mm, a dispersion was obtained. The viscosity of the dispersion was such that η₁ was 200 mPa·s and η₂ was 130 mPa·s, and the thixotropy ratio was 1.5. With respect to this dispersion, the dispersion stability was “2” and the coating property was “2”.

Further, this dispersion was mixed with an epoxy varnish in the same manner as in Ex. 11, to obtain a coating liquid. The viscosity of the coating liquid was such that η₁ was 310 mPa·s and η₂ was 220 mPa·s, and the thixotropy ratio was 1.4. The film properties of this coating liquid were “2” and the permittivity was 3.2.

### [Ex. 23]

A dispersion was obtained in the same manner as in Ex. 22 except that powder X4 was used instead of powder X3. The viscosity of this dispersion was such that η₁ was 190 mPa·s and η₂ was 120 mPa·s, and the thixotropy ratio was 1.6. With respect to this dispersion, the dispersion stability was “2”, and the coating property was “2”. The viscosity of a coating liquid obtained by mixing this dispersion with the epoxy varnish in the same manner as in Ex. 11, was such that η₁ was 300 mPa·s and η₂ was 200 mPa·s, and the thixotropy ratio was 1.5.

### [Ex. 24]

A dispersion was obtained in the same manner as in Ex. 22 except that powder X5 was used instead of powder X3. The viscosity of this dispersion was such that η₁ was 220 mPa·s and η₂ was 140 mPa·s, and the thixotropy ratio was 1.6. With respect to this dispersion, the dispersion stability was “2”, and the coating property was “2”. The viscosity of a coating liquid obtained by mixing this dispersion with the epoxy varnish in the same manner as in Ex. 11, was such that η₁ was 320 mPa·s and η₂ was 230 mPa·s, and the thixotropy ratio was 1.5.

### [Ex. 25 to 30]

A dispersion was obtained in the same manner as in Ex. 1, except for changing the composition ratio as shown in Table 5. With respect to the obtained dispersion, ni and η₂ were measured, the thixotropy ratio was calculated, and the low temperature dispersion stability was evaluated. The results are shown in Table 6.

TABLE 5

| | | | | a₁ | a₂ | a₃ | b₁ |
|---|---|---|---|---|---|---|---|
| | Powder | Surfactant | Solvent | [mass %] | [mass %] | [mass %] | [%] |
| Ex. 25 | X6 | Compound 2 | CHN | 45 | 5 | 50 | 11.1 |
| Ex. 26 | X6 | Compound 2 | NMP | 45 | 5 | 50 | 11.1 |
| Ex. 27 | X6 | Compound 2 | DMAc | 45 | 5 | 50 | 11.1 |
| Ex. 28 | X6 | Compound 2 | MEK | 45 | 5 | 50 | 11.1 |
| Ex. 29 | X7 | Compound 2 | NMP | 45 | 5 | 50 | 11.1 |
| Ex. 30 | X6 | Compound 2 | Butyl | 45 | 5 | 50 | 11.1 |
| | | | acetate | | | | |

TABLE 6

| | η₁ | η₂ | η₁/η₂ | Low temperature |
|---|---|---|---|---|
| | [mPa · s] | [mPa · s] | [—] | dispersion stability |
| Ex. 25 | 300 | 280 | 1.1 | 2 |
| Ex. 26 | 180 | 160 | 1.1 | 2 |
| Ex. 27 | 240 | 220 | 1.1 | 2 |
| Ex. 28 | 520 | 380 | 1.4 | 2 |
| Ex. 29 | 10 | 10 | 1.0 | 1 |
| Ex. 30 | 210 | 90 | 2.3 | 1 |

### [Ex. 31 to 32] Production Example for Laminate

The dispersion in Ex. 11 was applied to a copper foil with a thickness of 18 μm, dried at 100° C. for 15 minutes under a nitrogen atmosphere, and further heated at 350° C. for 15 minutes, followed by annealing to obtain a laminate having a resin layer and the foil 1 adhered and laminated. The resin layer was excellent in surface smoothness and had a uniform thickness in a thickness of 7 μm (Ex. 31).

A laminate having a resin layer and the foil 1 adhered and laminated, was obtained in the same manner by using the dispersion in Ex. 17 instead of the dispersion in Ex. 1. The resin layer had coating spots on the surface, and it was not possible to obtain a resin layer having a uniform thickness (Ex. 32).

### INDUSTRIAL APPLICABILITY

The film, fiber reinforced film, prepreg, metal clad laminate, printed board or the like obtainable by the present invention is useful as a covering article for e.g. an antenna component, a printed board, an aircraft part, an automotive part, a sports equipment, a food industry equipment, a saw, a sliding bearing or the like.

This application is a continuation of PCT Application No. PCT/JP2018/047952, filed on Dec. 26, 2018, which is based upon and claims the benefit of priority from Japanese Patent Application 2017-252475 filed on Dec. 27, 2017, Japanese Patent Application No. 2018-094781 filed on May 16, 2018 and Japanese Patent Application No. 2018-160700 filed on Aug. 29, 2018. The contents of those applications are incorporated herein by reference in their entireties.

What is claimed is:

1. A dispersion comprising an organic solvent and a powder so that the powder is dispersed in the organic solvent, wherein the powder is a powder containing a tetrafluoroethylene type polymer with a melt viscosity at 380° C. of from 1×10² to 1×10⁶ Pa·s; the viscosity is from 50 to 10,000 mPa·s; and the thixotropy ratio calculated by dividing the viscosity measured under the condition of rotational speed of 30 rpm by the viscosity measured under the condition of rotational speed of 60 rpm is from 1.0 to 2.2.

2. The dispersion according to claim 1, wherein the viscosity is from 100 to 10,000 mPa·s, and the thixotropy ratio is from 1.4 to 2.2.

3. The dispersion according to claim 1, wherein the viscosity is from 50 to 3000 mPa·s, and the thixotropy ratio is from 1.0 to 1.5.

4. The dispersion according to claim 1, wherein the powder is a powder having a volume-reduced cumulative 50% diameter of from 0.05 to 4 μm and a volume-reduced cumulative 90% diameter of at most 8 μm.

5. The dispersion according to claim 1, wherein the tetrafluoroethylene type polymer contains units derived from a comonomer other than tetrafluoroethylene in an amount exceeding 0.5 mol % to all units of the polymer.

6. The dispersion according to claim 1, wherein the tetrafluoroethylene type polymer is a copolymer of tetrafluoroethylene and ethylene, a copolymer of tetrafluoroethylene and a perfluoro(alkyl vinyl ether), a copolymer of tetrafluoroethylene and hexafluoropropylene, or a tetrafluoroethylene type polymer having at least one type of functional group selected from the group consisting of a carbonyl group-containing group, a hydroxy group, an epoxy group, an amide group, an amino group and an isocyanate group.

7. The dispersion according to claim 1, wherein the tetrafluoroethylene type polymer is a polytetrafluoroethylene containing units derived from tetrafluoroethylene in an amount of at least 99.5 mol %, to all units of the polymer.

8. The dispersion according to claim 1, wherein the organic solvent is methyl ethyl ketone, toluene, xylene, cyclohexane, methylcyclohexane, cyclohexanone, cyclopentanone, N,N-dimethylacetamide or N-methyl-2-pyrrolidone.

9. The dispersion according to claim 1, wherein the content of the powder is from 5 to 50 mass %, to the total of the organic solvent and the powder.

10. The dispersion according to claim 1, which further contains a surfactant.

11. The dispersion according to claim 10, wherein the surfactant is a surfactant having a fluorinated group and a hydrophilic group.

12. The dispersion according to claim 11, wherein the hydrophilic group which the surfactant has, is a polyoxyethylene group, a polyoxypropylene group, an oxybutylene group, an amino group, a ketone group, a carboxy group or a sulfonic group.

13. The dispersion according to claim 11, wherein the fluorinated group which the surfactant has, is a perfluoroalkyl group or a perfluoroalkenyl group.

14. The dispersion according to claim 10, wherein the surfactant is a polymeric compound having a fluorinated hydrocarbon group and a hydrophilic group in a side chain, wherein the main chain is made of a carbon chain derived from an ethylenically unsaturated monomer, and said fluorinated hydrocarbon group is a group having a tertiary carbon atom to which a plurality of monovalent fluorinated hydrocarbon groups are bonded.

15. The dispersion according to claim 1, wherein the content of the powder is from 35 to 70 mass % to the total of the organic solvent, the powder and the surfactant.

16. A method for producing a metal laminate, which comprises forming a dispersion as defined in claim 1 into a resin layer on the surface of a metal film to obtain a metal film having a resin layer on the surface.

17. The method for producing a metal laminate according to claim 16, wherein the thickness of the resin layer is from 1 to 20 μm.

18. A method for producing a printed board, which comprises producing a metal laminate by the production method as defined in claim 16 and etching the metal film to form a patterned circuit.
